(19) United States
(12) Patent Application Publication
(10) Pub. No.: US 2024/0243104 A1
(43) Pub. Date: Jul. 18, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Seunghoon Yeon, Suwon-si (KR); Seungryong Oh, Suwon-si (KR); Junho Lee, Suwon-si (KR)

(21) Appl. No.: 18/513,863

(22) Filed: Nov. 20, 2023

(30) Foreign Application Priority Data
Jan. 18, 2023 (KR) 10-2023-0007238

(51) Int. Cl. H01L 25/065; H01L 23/00; H01L 23/31

(52) U.S. Cl. CPC H01L 25/0657; H01L 23/3107; H01L 24/13; H01L 24/16; H01L 24/32; H01L 24/73; H01L 2224/1357; H01L 2224/16148; H01L 2224/16227; H01L 2224/32145; H01L 2224/32225; H01L 2224/73204; H01L 2225/06513; H01L 2225/06541; H01L 2924/1431; H01L 2924/1436; H01L 2924/1437; H01L 2924/1438

(57) ABSTRACT

A semiconductor package includes a first semiconductor chip and a second semiconductor chip. The first semiconductor chip includes a plurality of electrode bundles arranged in an array in a first substrate and each having a plurality of through electrodes penetrating the first substrate, a backside insulating layer on a backside surface of the first substrate through which end portions of the through electrodes are exposed, and a plurality of electrode pads respectively provided on the electrode bundles. The backside insulating layer has a first trench formed between the through electrodes of a first electrode bundle. A first electrode pad is disposed on the through electrodes of a first electrode bundle and includes a protruding portion that fills the first trench of the backside insulating layer.

### PRIORITY STATEMENT

This application claims priority under 35 U.S.C. § 119 to Korean Patent Application No. 10-2023-0007238, filed on Jan. 18, 2023 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a multi-chip package including a plurality of different stacked chips and a method of manufacturing the same.

### 2. Description of the Related Art

In a 3D chip stack package including stacked chips, signals may be transmitted through a bundle of through silicon vias (TSVs) connected to one electrode pad in order to improve power performance. However, when forming a passivation layer to expose the bundle of through silicon vias on a backside surface of the chip and forming an electrode pad on the plurality of through silicon vias, there is a problem that adhesion may not properly occur between the electrode pad and the passivation layer and between the exposed through silicon vias and the passivation layer.

### SUMMARY

Example embodiments provide a semiconductor package having a structure capable of improving signal transmission characteristics and increasing adhesion between a passivation layer on a backside surface of a semiconductor chip and an electrode pad.

Example embodiments provide a method of manufacturing the semiconductor package.

In accordance with an aspect of the disclosure, a semiconductor packages includes a package substrate; a first semiconductor chip stacked on the package substrate, the first semiconductor chip including a first substrate having first and second surfaces opposite to each other, a plurality of electrode bundles each including a plurality of through electrodes that are adjacent to each other, the plurality of through electrodes penetrating the first substrate, a backside insulating layer on the second surface of the first substrate through which end portions of the plurality of through electrodes are exposed, and a plurality of electrode pads respectively provided on the plurality of electrode bundles; a second semiconductor chip stacked on the first semiconductor chip by way of conductive bumps; and an adhesive layer filling a space between the conductive bumps between the first semiconductor chip and the second semiconductor chip, the adhesive layer attaching the first semiconductor chip to the second semiconductor chip, wherein the backside insulating layer has a first trench formed between the end portions of the plurality of through electrodes of a first electrode bundle of the plurality of electrode bundles, wherein a first electrode pad of the plurality of electrode pads is electrically connected to the plurality of through electrodes of the first electrode bundle of the plurality of electrode bundles, and wherein the first electrode pad has a protruding portion that fills the first trench of the backside insulating layer.

In accordance with an aspect of the disclosure, a semiconductor package includes a first semiconductor chip including a first substrate having first and second surfaces opposite to each other, a plurality of electrode bundles arranged in an array in the first substrate, each of the plurality of electrode bundles including a plurality of through electrodes penetrating the first substrate, a plurality of first bonding pads on the first surface of the first substrate and electrically connected to the plurality of through electrodes, a backside insulating layer on the second surface of the first substrate through which end portions of the plurality of through electrodes are exposed, and a plurality of electrode pads respectively provided on the plurality of electrode bundles; and a second semiconductor chip including a second substrate having first and second surfaces opposite to each other and a plurality of third bonding pads provided on the first surface of the second substrate, the second semiconductor chip being stacked on the first semiconductor chip by way of conductive bumps formed on the third bonding pads respectively, wherein the backside insulating layer has a first trench formed between the plurality of through electrodes of a first electrode bundle of the plurality of electrode bundles, and wherein a first electrode pad is disposed on the plurality of through electrodes of the first electrode bundle and includes a protruding portion that fills the first trench of the backside insulating layer.

In accordance with an aspect of the disclosure, a semiconductor package includes a first semiconductor chip including a first substrate having first and second surfaces opposite to each other, a plurality of electrode bundles arranged in an array in the first substrate, each of the plurality of electrode bundles including a plurality of through electrodes penetrating the first substrate, a plurality of first bonding pads on the first surface of the first substrate and electrically connected to the plurality of through electrodes, a backside insulating layer on the second surface of the first substrate through which end portions of the plurality of through electrodes are exposed, and a plurality of electrode pads respectively provided on the plurality of electrode bundles; a second semiconductor chip stacked on the first semiconductor chip by way of conductive bumps; an adhesive layer filling a space between the conductive bumps between the first semiconductor chip and the second semiconductor chip, the adhesive layer attaching the first semiconductor chip to the second semiconductor chip; and a sealing member on the first semiconductor chip covering a side surface of the second semiconductor chip, wherein the backside insulating layer includes a first passivation layer covering the second surface of the first substrate and sidewalls of the end portions of the plurality of through electrodes protruding from the second surface; and a second passivation layer formed on the first passivation layer and having a first trench formed between the plurality of through electrodes of a first electrode bundle, and wherein a first electrode pad is disposed on the plurality of through electrodes of the first electrode bundle and includes a protruding portion that fills the first trench of the second passivation layer.

According to example embodiments, in a method of manufacturing a semiconductor package, a first semiconductor chip including a first substrate having first and second surfaces opposite to each other and a plurality of electrode bundles each including a plurality of through electrodes extending through the first substrate and adjacent to each other is formed. A second surface of the first substrate is partially removed to expose end portions of the through electrodes. A back insulating layer is formed on the second surface of the first substrate to cover sidewalls of the exposed end portions of the through electrodes and have at least one trench formed between the end portions of the through electrodes of one electrode bundle. A plurality of electrode pads are formed on the electrode bundles on the backside insulating layer. A second semiconductor chip including a second substrate having third and fourth surfaces opposite to each other is formed. The second semiconductor chip is stacked on the first semiconductor chip via conductive bumps.

According to example embodiments, a semiconductor package may include a first semiconductor chip and a second semiconductor chip stacked on the first semiconductor chip via conductive bumps. The first semiconductor chip may include a first substrate, a plurality of electrode bundles each including a plurality of through electrodes penetrating through the first substrate and adjacent to each other, a backside insulating layer on a backside surface of the first substrate to expose end portions of the through electrodes, and a plurality of electrode pads respectively provided on the electrode bundles.

The backside insulating layer may have at least one trench formed between the exposed end portions of the through electrodes of one electrode bundle. One electrode pad may be disposed on the exposed surfaces of the through electrodes of one electrode bundle. The electrode pad may include a protruding portion that fills the trench formed in an upper surface of the backside insulating layer.

Accordingly, the protruding portion of the electrode pad may serve as an anchor to increase adhesion between the electrode pad and the backside insulating layer and between the electrode pad and the through electrodes.

### BRIEF DESCRIPTION OF THE DRAWINGS

Example embodiments will be more clearly understood from the following detailed description taken in conjunction with the accompanying drawings. FIGS. 1 to 36 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is an enlarged plan view illustrating portion ‘B’ of FIG. 2.

FIG. 4 is a plan view illustrating an electrode bundle having through electrodes exposed by a backside insulating layer of FIG. 3.

FIGS. 5 to 21 are views illustrating a method of manufacturing a semiconductor package in accordance with example embodiments.

FIG. 22 is a plan view illustrating an electrode bundle having through electrodes exposed by a backside insulating layer of a lower semiconductor chip in accordance with example embodiments.

FIG. 23 is a plan view illustrating an electrode bundle having through electrodes exposed by a backside insulating layer of a lower semiconductor chip in accordance with example embodiments.

FIG. 24 is a plan view illustrating an electrode bundle having through electrodes exposed by a backside insulating layer of a lower semiconductor chip in accordance with example embodiments.

FIG. 25 is a cross-sectional view illustrating a semiconductor package in accordance with example embodiments.

FIG. 26 is an enlarged cross-sectional view illustrating portion ‘F’ in FIG. 25.

FIGS. 27 to 36 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

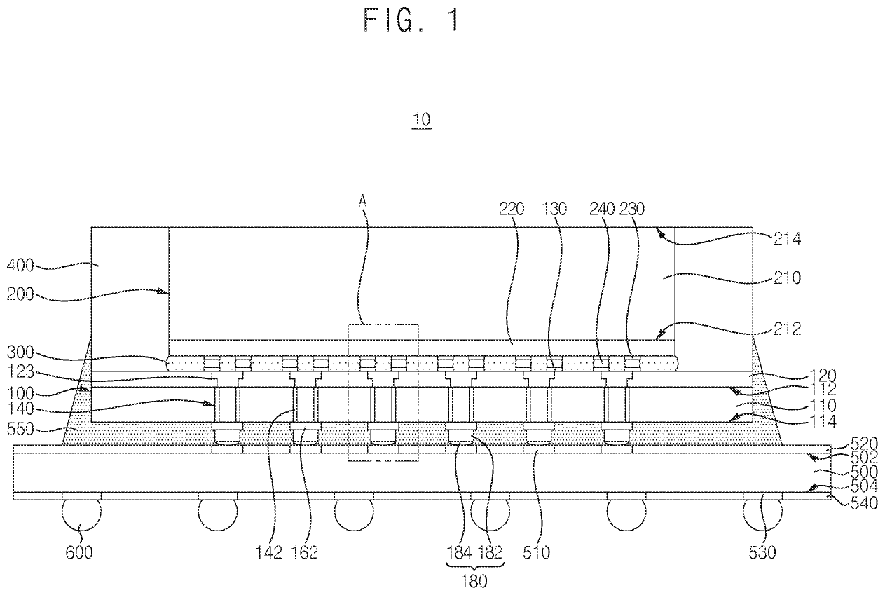

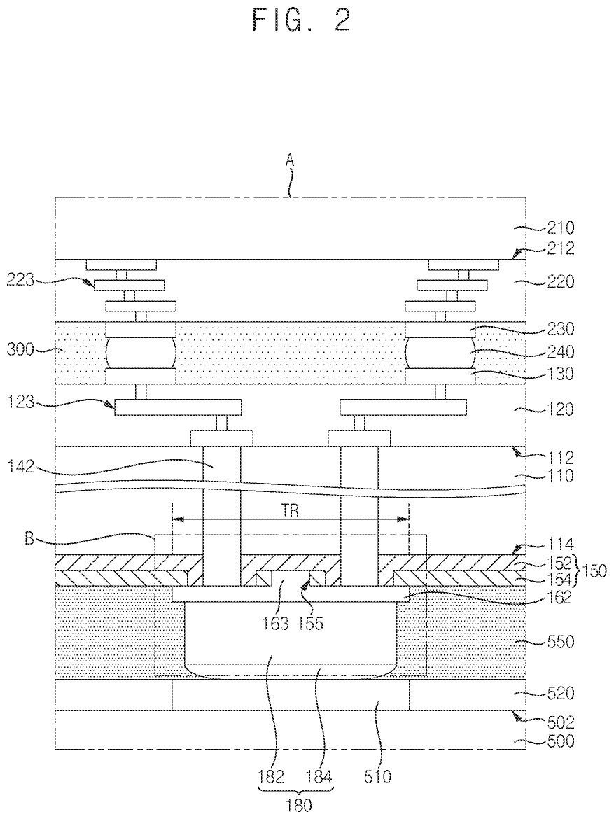

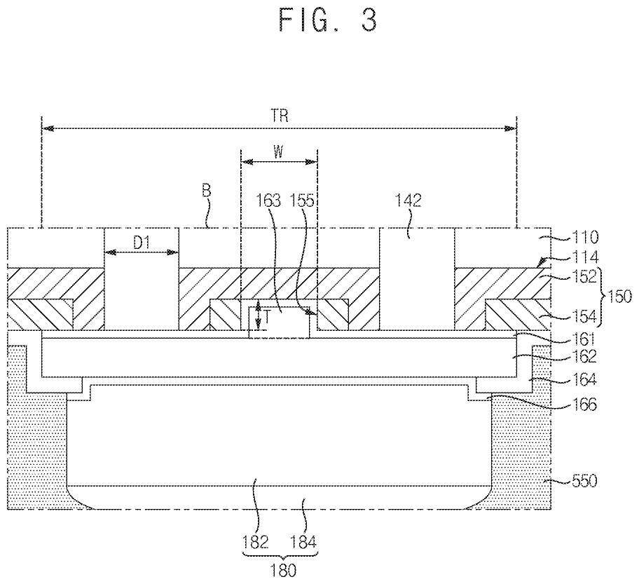

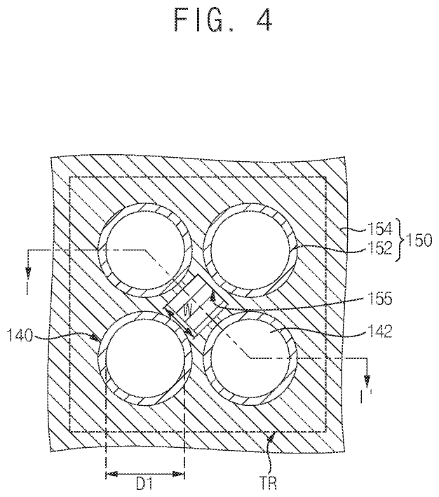

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged plan view illustrating portion ‘B’ of FIG. 2. FIG. 4 is a plan view illustrating an electrode bundle having through electrodes exposed by a backside insulating layer of FIG. 3. FIG. 3 is a cross-sectional view taken along the line I-I′ in FIG. 4. FIG. 4 is a plan view of FIG. 3, wherein a third bonding pad on the backside insulating layer is omitted.

Referring to FIGS. 1 to 4, a semiconductor package 10 may include a first semiconductor chip 100 and a second semiconductor chip 200 stacked on the first semiconductor chip 100. In addition, the semiconductor package 10 may include an adhesive layer 300 interposed between the first and second semiconductor chips 100 and 200, a sealing member 400, a package substrate 500 on which the stacked first and second semiconductor chips 100 and 200 are mounted, and external connection members 600 provided on a lower surface of the package substrate 500.

In addition, the semiconductor package 10 may be a multi-chip package (MCP) including different types of semiconductor chips. The semiconductor package 10 may be a system in package (SIP) including a plurality of semiconductor chips stacked or arranged in one package to perform all or most of the functions of an electronic system.

The semiconductor package 10 may include the first semiconductor chip 100 as a logic chip and the second semiconductor chips 200 as a memory chip, sequentially stacked. The first semiconductor chip 100 may be a logic chip including a logic circuit. The logic chip may be a controller that controls memory devices of the second semiconductor chip. The first semiconductor chip may be a processor chip such as an ASIC, an application processor (AP), etc. serving as a host such as a CPU, GPU, or SOC. The second semiconductor chip may include DRAM, SRAM, etc.

In this embodiment, the semiconductor package as a multi-chip package is illustrated as including two stacked first and second semiconductor chips 100 and 200. However, the invention is not limited thereto, and for example, the semiconductor package may include 4, 8, 12, or 16 stacked semiconductor chips.

In example embodiments, the first semiconductor chip 100 may include a first substrate 110, a first front wiring layer 120, a plurality of first bonding pads 130, a plurality of electrode bundles 140, a backside insulating layer 150 and a plurality of electrode pads 162 as second bonding pads. The first bonding pads 130 and electrode pads 162 may be chip pads of the first semiconductor chip 100 and form terminals of the first semiconductor chip 100 to transmit signals and/or supply voltages between an internal wiring and/or internal circuit of the first semiconductor chip 100 and an external source. The first bonding pads 130 and electrode pads 162 (and other chip pads described herein) may be provided on or near an external surface of the device and may generally have a planar surface area (often larger than a corresponding surface area of the internal wiring to which they are connected) to promote connection to a further terminal, such as a bump or solder ball, and/or an external wiring. In addition, the first semiconductor chip 100 may further include first conductive bumps 180 as first conductive connection members respectively provided on the electrode pads 162. The first semiconductor chip 100 may be mounted on the package substrate 500 via the first conductive bumps 180. For example, the first conductive bumps 180 may include solder bumps.

In particular, the first substrate 110 may have a first surface 112 and a second surface 114 opposite to the first surface 112. The first surface 112 may be an active surface, and the second surface 114 may be an inactive surface. Circuit patterns may be provided on the first surface 112 of the first substrate 110 and may be formed with active regions (doped with charge carrier dopants) within the first surface 112 of the first substrate 110. For example, the first substrate 110 may be a single crystal silicon (bulk silicon) substrate. The circuit patterns may include transistors, capacitors, diodes, etc. The circuit patterns may constitute circuit elements. Accordingly, the first semiconductor chip 100 may be a semiconductor device in which a plurality of the circuit elements are formed.

For example, the first semiconductor chip may be a logic chip including a logic circuit. The logic chip may be a controller that controls memory elements of the second semiconductor chip. The first semiconductor chip may be a processor chip such as ASIC, an application processor (AP), etc. serving as a host such as a CPU, GPU, or SOC.

The first front wiring layer 120 may be provided on the first surface 112 of the first substrate 110, that is, an active surface of the first substrate 110. The first front wiring layer 120 may include a plurality of insulating layers and metal wirings 123 in the insulating layers. In addition, redistribution pads may be provided in an outermost insulating layer of the first front wiring layer 120, and the first bonding pads 130 may be provided on the redistribution pads. In addition, the first semiconductor chip 100 may comprise a passivation layer (not shown) on the first front wiring layer to form the outermost layer of the first semiconductor chip 100. Openings may be formed within this passivation layer to expose the first bonding pads 130 with respect to this passivation layer.

In example embodiments, the plurality of electrode bundles 140 may be arranged in an array form in the first substrate 110 (e.g., regularly distributed in two dimensions across one or more portions of the first substrate 110). Each of the electrode bundles 140 may include at least three through electrodes (through silicon vias, TSVs) 142 adjacent to each other. The through electrode 142 may extend from the first surface 112 to the second surface 114 of the first substrate 110. A first end portion of the through electrode 142 may contact the metal wiring of the first front wiring layer 120. However, the invention is not limited thereto, and for example, the through electrode 142 may penetrate the first front wiring layer and directly contact the first bonding pad 130.

The backside insulating layer 150 may be provided on the second surface 114 of the first substrate 110, that is, a backside surface. The backside surface may be an inactive surface without logic circuits and/or transistors formed with the backside surface. The backside insulating layer 150 may be provided on the second surface 114 of the first substrate 110 and expose end portions, e.g., second end portions of the through electrodes 142 may be exposed through the backside insulating layer 150. The backside insulating layer 150 may have at least one trench 155 formed between the end portions of the through electrodes 142 of one electrode bundle 140.

In particular, the backside insulating layer 150 may include a first passivation layer 152 and a second passivation layer 154 stacked on the first passivation layer 152. The first passivation layer 152 may cover the second surface 114 of the first substrate and sidewalls of end portions of the through electrodes 142 protruding from the second surface 114. The trench 155 may be provided in the second passivation layer 154 between adjacent through electrodes 142. The first passivation layer 152 may be exposed by the trench 155. For example, a bottom face of the trench 155 may be an exposed portion of the first passivation layer 152.

The first passivation layer 152 and the second passivation layer 154 may each be formed of an insulating material. The first passivation layer 152 may include and/or be formed of an oxide such as silicon oxide (SiO₂), and the second passivation layer 154 may include and/or be formed of a nitride such as silicon nitride (SiN). Thicknesses of the first and second passivation layers 152 and 154 may be within a range of 0.5 μm to 2.5 μm. A depth T of the trench 155 may be within a range of 0.5 μm to 2.5 μm. A width W of the trench 155 may be within a range of 1 μm to 3 μm.

An upper surface of the second passivation layer 154 may be positioned on the same plane as an exposed surface of the end portion of the through electrode 142. The upper surface of the second passivation layer 154 may be coplanar with an upper surface of the first passivation layer 152 that covers the side walls of the end portions of the through electrodes 142 protruding from the second surface 114. The upper surfaces of the second passivation layer 154 and the first passivation layer 152 may be upper surfaces when viewed, for example, in an orientation as shown in FIGS. 10, 12, 13, 15, and 16. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The electrode pads 162 as the second bonding pads may be provided on the backside insulating layer 150. The electrode pads 162 may be respectively disposed on the electrode bundles 140. One electrode pad 162 may be disposed on and contact exposed surfaces of the through electrodes 142 of one electrode bundle 140. One electrode pad 162 may be electrically connected to the through electrodes 142 of one electrode bundle 140. Accordingly, one electrode pad 162 may be electrically connected to the first bonding pads 130 through the through electrodes 142 of the electrode bundle 140.

As illustrated in FIGS. 3 and 4, one electrode bundle 140 may have four through electrodes 142 disposed adjacent to each other in a pad region TR. The second passivation layer 154 may have one trench 155 formed between the four through electrodes 142 (e.g., in a middle region among the four through electrodes 142). When viewed from a plan view, the trench 155 may have a diamond shape. The width, depth, shape, etc. of the trench 155 may be determined by the number of the through electrodes 142 around the trench and a distance between the through electrodes.

The electrode pad 162 may include a protruding portion 163 filling the trench 155 formed in the upper surface of the backside insulating layer 150. The protruding portion 163 may serve as an anchor to increase adhesion between the electrode pad 162 and the backside insulating layer 150 and between the electrode pad 162 and the through electrodes 142.

In addition, one electrode pad 162 may be electrically connected to four through electrodes 142 of one electrode bundle 140. When a power signal is transmitted through the electrode pad 162, the power signal may be transmitted through the four through electrodes 142 of the electrode bundle 140 that are connected to the electrode pad 162 in parallel to each other, and electrical transmission characteristics may be improved by a voltage drop (IR drop) effect.

The numbers, sizes, arrangements, etc. of the metal wirings, the first bonding pads, the through electrodes and the electrode pads of the first front wiring layer are provided as examples, and it may be understood that the present inventive concept is not limited thereto.

In example embodiments, the second semiconductor chip 200 may include a second substrate 210, a second front wiring layer 220 and a plurality of third bonding pads 230. The third bonding pads 230 may be chip pads of the second semiconductor chip 200 and form terminals of the second semiconductor chip 200 to connect internal circuits of the second semiconductor chip to an external source. In addition, the second semiconductor chip 200 may further include second conductive bumps 240 as second conductive connection members respectively provided on the third bonding pads 230. The second semiconductor chip 200 may be mounted on the first semiconductor chip 100 via the second conductive bumps 240. For example, the second conductive bumps 240 may include solder bumps.

The second substrate 210 may have a first surface 212 and a second surface 214 opposite to the first surface 212. The first surface may be an active surface, and the second surface may be an inactive surface. Circuit elements may be formed on and/or within the first surface 212 of the second substrate 210. The circuit element may include a plurality of memory devices. Examples of the memory device may include a volatile semiconductor memory device and a non-volatile semiconductor memory device.

The second front wiring layer 220 may include a plurality of insulating layers sequentially stacked on the first surface 212 of the second substrate 210 and metal wirings 223 in the insulating layers. A plurality of the third bonding pads 230 may be provided on the second front wiring layer 220. The third bonding pad 230 may be provided on an uppermost wiring among the metal wirings 223. In addition, the second semiconductor chip 200 may include a passivation layer (not shown) on the second front wiring layer 220 covering the third bonding pads 230. Openings in this passivation layer may expose the third bonding pads 230.

The sizes and thicknesses of the first and second semiconductor chips, the metal wirings of the second front wiring layer and the third bonding pads may be provided as examples, and it may be understood that the present inventive concept is not limited thereto. For example, the first semiconductor chip may have a thickness range of 50 μm to 120 μm, and the second semiconductor chip may have a thickness range of 40 μm to 700 μm.

The second conductive bumps 240 may be respectively provided on the third bonding pads 230. A pitch between adjacent ones of the second conductive bumps 240 may be within a range of 15 μm to 35 μm. For example, the second conductive bump 240 of the second semiconductor chip 200 may be bonded to the first bonding pad 130 of the first semiconductor chip by a flip chip bonding process. Accordingly, the third bonding pad 230 of the second semiconductor chip 200 may be electrically connected to the electrode pad 162 of the first semiconductor chip 100 through the second conductive bump 240.

In example embodiments, the adhesive layer 300 may be provided to fill a space between the second conductive bumps 240 between the first semiconductor chip 100 and the second semiconductor chip 200. For example, the adhesive layer may include a non-conductive film (NCF).

For example, the second semiconductor chip 200 and the first semiconductor chip 100 may be attached to each other by a thermal compression process using the non-conductive film. In the thermal compression process, the non-conductive film may be liquefied and may have fluidity, and may flow between the second semiconductor chip 200 and the first semiconductor chip 100 and the second conductive bumps 240, and then may be cured to fill spaces between the second conductive bumps 240. A portion of the cured adhesive layer 300 may protrude from a side surface of the second semiconductor chip 200.

In example embodiments, the sealing member 400 may cover the second semiconductor chip 200 on the first semiconductor chip 100. The sealing member 400 may cover the side surface of the second semiconductor chip 200. An upper surface, that is, the backside surface of the second semiconductor chip 200 may be exposed by the sealing member 400. For example, the sealing member 400 may include a thermosetting resin or the like.

In example embodiments, the package substrate 500 may be a substrate having an upper surface 502 and a lower surface 504 facing each other. For example, the package substrate 500 may be a printed circuit board (PCB). The printed circuit board may be a multilayer circuit board having vias and various circuits therein.

The first semiconductor chip 100 may be mounted on the package substrate 500 by way of the first conductive bumps 180. The first semiconductor chip 100 may be disposed such that the second surface 114 of the first substrate 110 of the first semiconductor chip 100 faces the package substrate 500. The first conductive bump 180 of the first semiconductor chip 100 may be bonded to a substrate pad 510 on the upper surface 502 of the package substrate 500. A planar area of the first semiconductor chip 100 may be smaller than a planar area of the package substrate 500. When viewed from a plan view, the first semiconductor chip 100 may be disposed in the package substrate 500.

In example embodiments, an underfill member 550 may be interposed between the first semiconductor chip 100 and the package substrate 500. For example, the underfill member may include an epoxy material to reinforce a gap between the first semiconductor chip 100 and the package substrate 500.

External connection pads 530 may be provided on the lower surface 504 of the package substrate 500, and external connection members 600 may be respectively disposed on the external connection pads 530. For example, the external connection member 600 may be a solder ball. The semiconductor package 10 may be mounted on a module substrate by way of the solder balls to form a memory module.

As mentioned above, the semiconductor package 10 may include the first semiconductor chip 100, and the second semiconductor chip 200 stacked on the first semiconductor chip 100 via the second conductive bumps 240. The first semiconductor chip 100 may include the first substrate 110, the plurality of electrode bundles 140 each including the plurality of through electrodes 142 penetrating the first substrate 110 and adjacent to each other, the backside insulating layer 150 provided on the second surface 114 of the first substrate 110 to expose one end portions of the through electrodes 142, and the plurality of electrode pads 162 respectively provided on the electrode bundles 140.

The backside insulating layer 150 may have at least one trench 155 formed between the exposed end portions of the through electrodes 142 of the one electrode bundle 140. One electrode pad 162 may be disposed on the exposed surfaces of through electrodes 142 of one electrode bundle 140. The electrode pad 162 may include the protruding portion 163 filling the trench 155 formed in the upper surface of the backside insulating layer 150.

Thus, the protruding portion 163 may serve as an anchor to increase adhesion between the electrode pad 162 and the backside insulating layer 150 and between the electrode pad 162 and the through electrodes 142.

Hereinafter, a method of manufacturing the semiconductor package of FIG. 1 will be described.

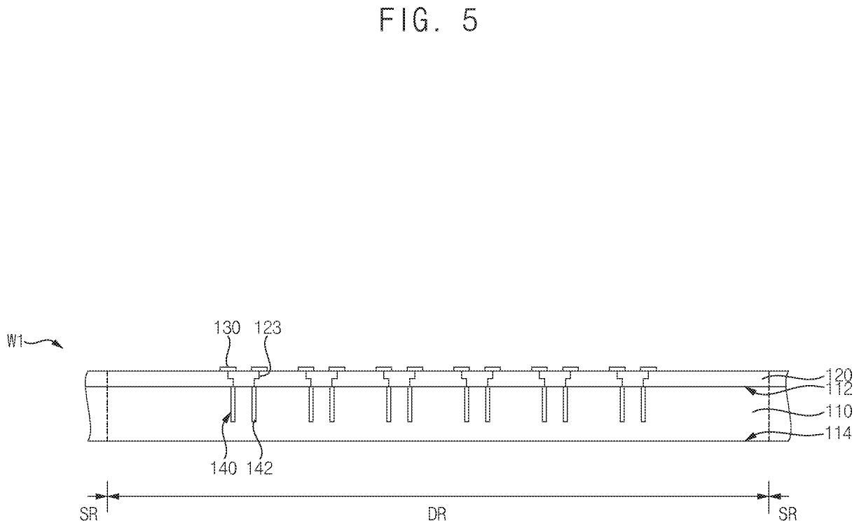

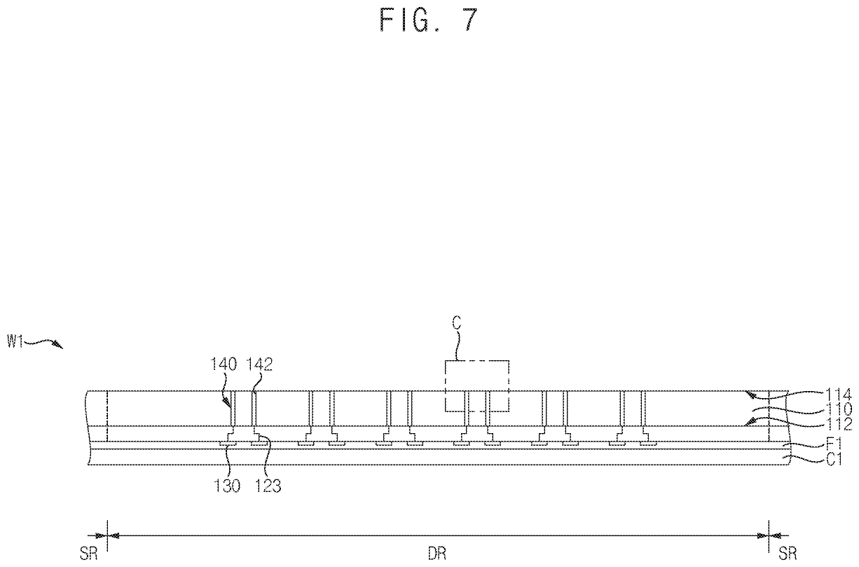

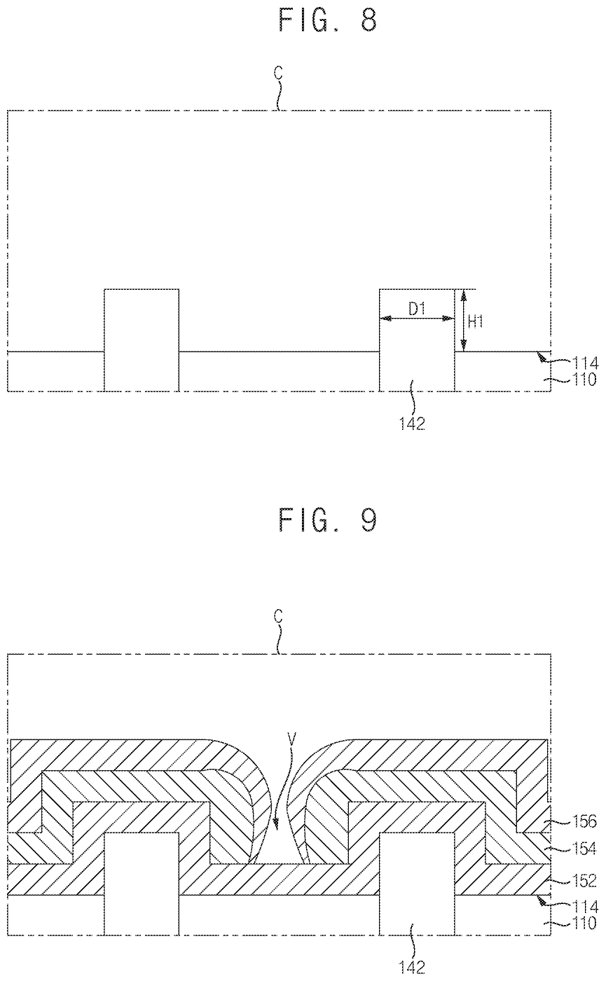

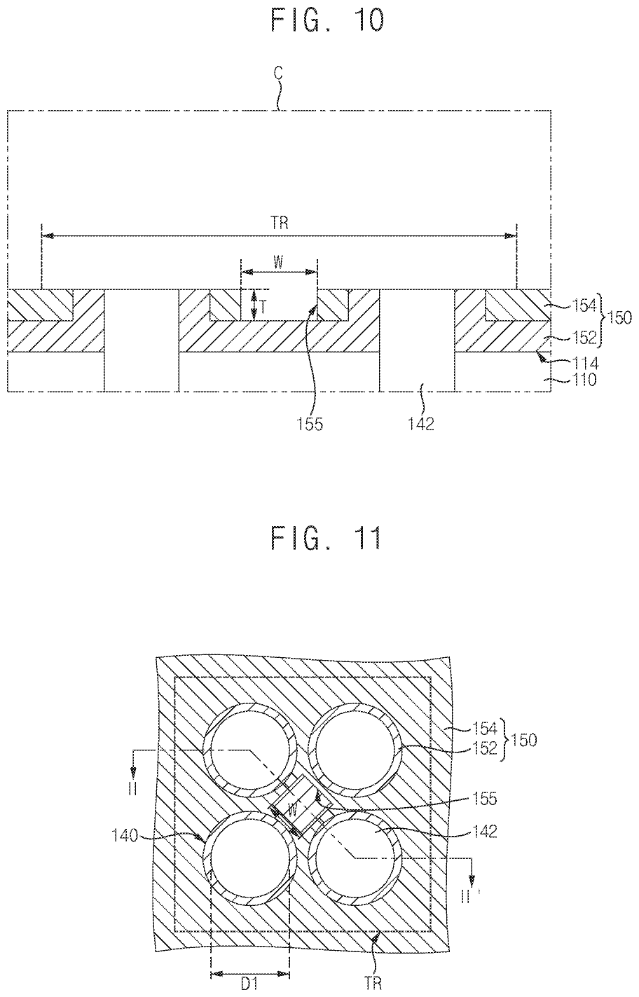

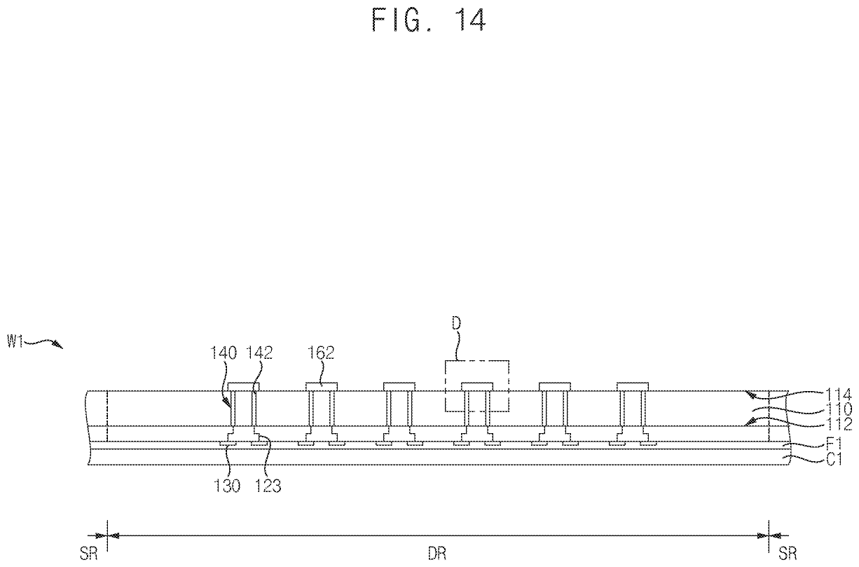

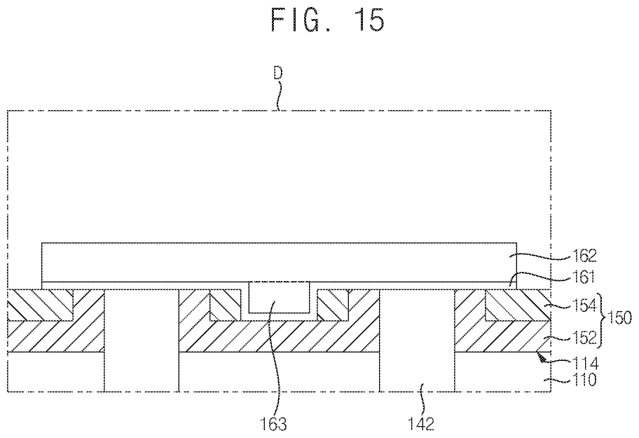

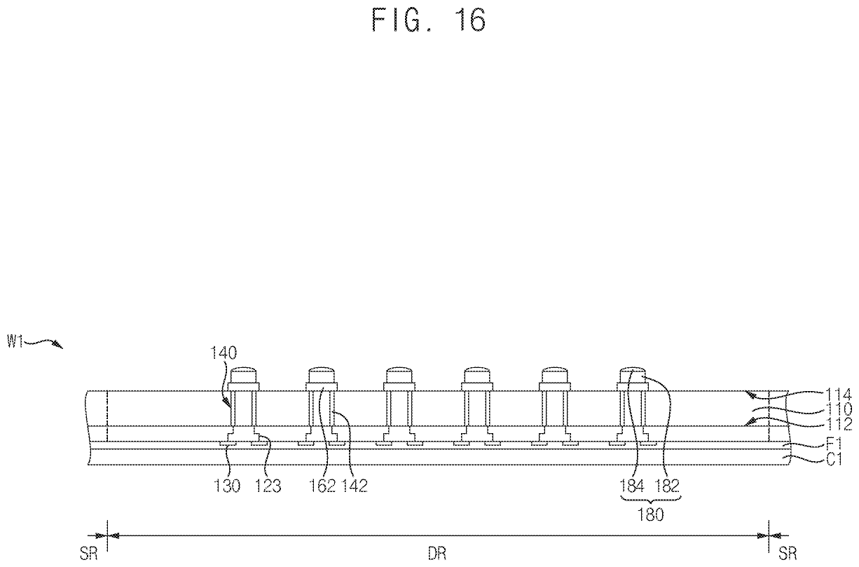

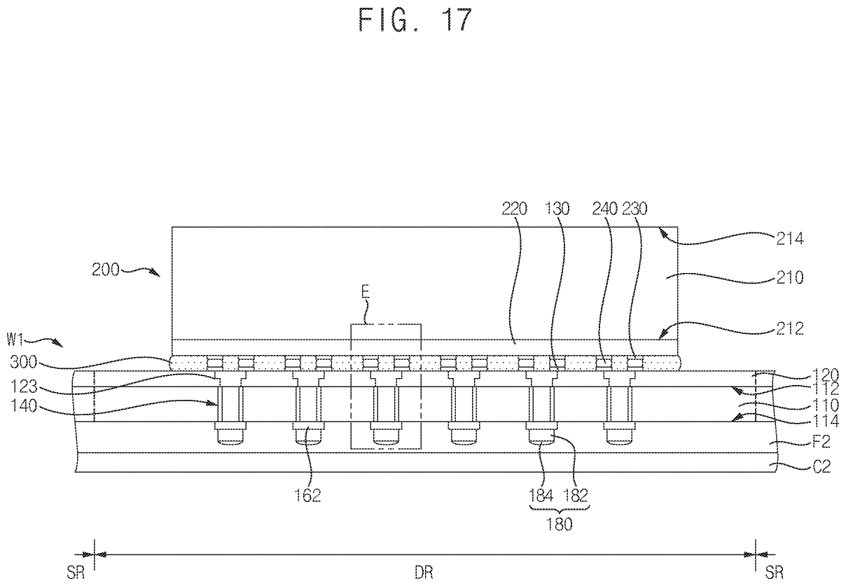

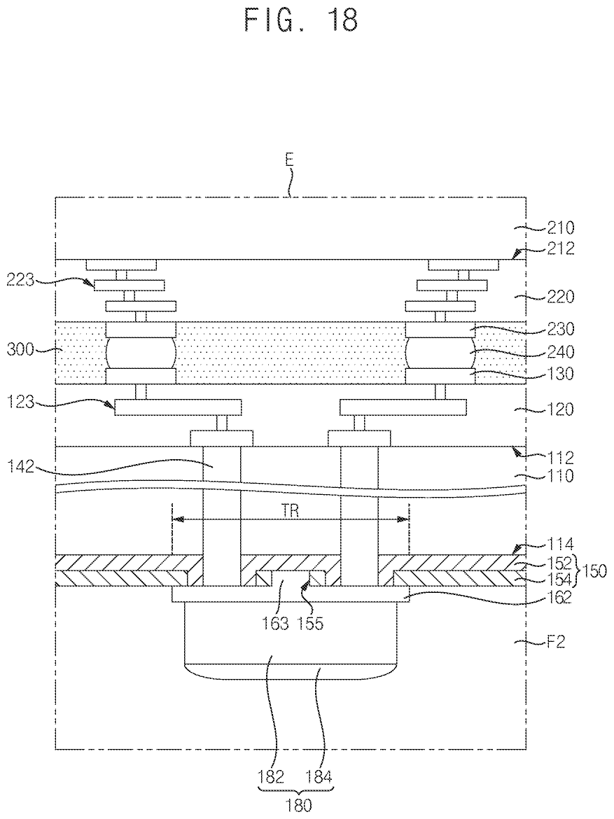

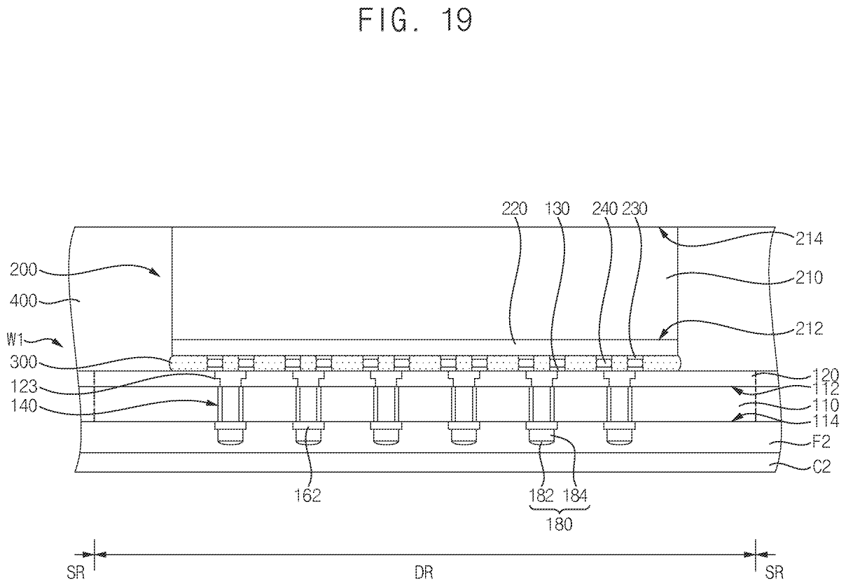

FIGS. 5 to 21 are views illustrating a method of manufacturing a semiconductor package in accordance with example embodiments. FIGS. 5 to 7, 14, 16, 17 and 19 to 21 are cross-sectional views illustrating a method of manufacturing a semiconductor package in accordance with example embodiments. FIGS. 8 to 10, 12 and 13 are enlarged cross-sectional views illustrating portion ‘C’ in FIG. 7. FIG. 11 is a plan view of FIG. 10. FIG. 10 is a cross-sectional view taken along the line II-II′ in FIG. 11. FIG. 15 is an enlarged cross-sectional view illustrating portion ‘D’ in FIG. 14. FIG. 18 is an enlarged cross-sectional view illustrating portion ‘E’ in FIG. 17.

Referring to FIG. 5, first, a first wafer W1 including a plurality of first semiconductor chips formed therein may be prepared.

In example embodiments, the first wafer W1 may include a first substrate 110 having a first surface 112 and a second surface 114 opposite to the first surface 112. The first substrate 110 may include a die region DR and a scribe lane region SR surrounding the die region DR. The first substrate 110 may be cut along the scribe lane region SR that divides the plurality of die regions DR of the first wafer W1 by a later sawing process to be individualized into a plurality of first semiconductor chips.

Circuit elements may be formed in the die region DR on the first surface 112 of the first substrate 110. The first semiconductor chip may be a logic chip including a logic circuit. The logic chip may be a controller that controls memory elements of a second semiconductor chip. The first semiconductor chip may be a processor chip such as ASIC, an application processor (AP), etc. serving as a host such as a CPU, GPU, or SOC.

For example, the first substrate 110 may be a semiconductor material such as silicon, germanium, or silicon-germanium, or III-V compounds, e.g., gallium phosphide (GaP), gallium arsenide (GaAs), gallium antimonide (GaSb), etc. In some embodiments, the first substrate 110 may be a silicon-on-insulator (SOI) substrate or a germanium-on-insulator (GOI) substrate.

The circuit elements may include, for example, transistors, capacitors, wiring structures, etc. The circuit elements may be formed on the first surface 112 of the first substrate 110 by performing a Fab process called a front end of line (FEOL) process for manufacturing semiconductor devices. A surface of the first substrate on which the FEOL process is performed may be referred to as a front side surface of the first substrate, and a surface of the first substrate opposite to the front side surface may be referred to as a backside surface. An insulation interlayer covering the circuit elements may be formed on the first surface 112 of the first substrate 110.

In example embodiments, the first wafer W1 may include a first front wiring layer 120 provided on the first surface 112 of the first substrate 110. The first front wiring layer 120 may include a metal wiring layer and a protective layer sequentially stacked on the first surface 112 of the first substrate 110. The first front wiring layer 120 may be formed by performing a wiring process called a back-end-of-line (BEOL) process.

The first front wiring layer 120 may include a plurality of insulating layers and metal wirings 123 in the insulating layers. For example, the insulating layers may be formed to include an oxide such as silicon oxide, carbon-doped oxide, or fluorine-doped oxide. The metal wirings may include a metal material such as aluminum (Al) or copper (Cu).

The first wafer W1 may include a plurality of first bonding pads 130 on the first front wiring layer 120. The first bonding pad 130 may be provided on an uppermost wiring among the metal wirings 123. For example, the first bonding pads 130 may be formed by a plating process. The first bonding pad 130 may include copper (Cu), aluminum (Al), tungsten, nickel (Ni), molybdenum (Mo), gold (Au), silver (Ag), chromium (Cr), tin (Sn), titanium (Ti), or an alloy thereof.

The first wafer W1 may include a plurality of electrode bundles 140. The plurality of electrode bundles 140 may be arranged in an array form. Each of the electrode bundles 140 may include at least three through electrodes (through silicon vias, TSVs) 142 adjacent to each other. The through electrode 142 may extend by a predetermined depth from the first surface 112 of the first substrate 110. A first end portion of the through electrode 142 may contact the metal wiring of the first front wiring layer. However, the invention is not limited thereto, and for example, the through electrode 142 may penetrate the first front wiring layer and directly contact the first bonding pad 130.

In this embodiment, one electrode bundle 140 may have four through electrodes 142 adjacent to each other. As will be described below, the four through electrodes 142 of one electrode bundle 140 may be electrically connected to one electrode pad (second bonding pad). When the electrode pad transmits a power signal, the power signal may be transmitted through the four through electrodes 142 of the electrode bundle 140 connected in parallel to each other to the electrode pad, resulting in a voltage drop (IR drop) effect. As a result, electrical transmission characteristics may be improved, and electrical connection may be maintained even if connection failure of some through electrodes occurs.

The numbers, sizes, arrangements, etc. of the metal wirings, the first bonding pads, and the through electrodes of the first front wiring layer are provided as examples, and it will be understood that the present inventive concept is not limited thereto.

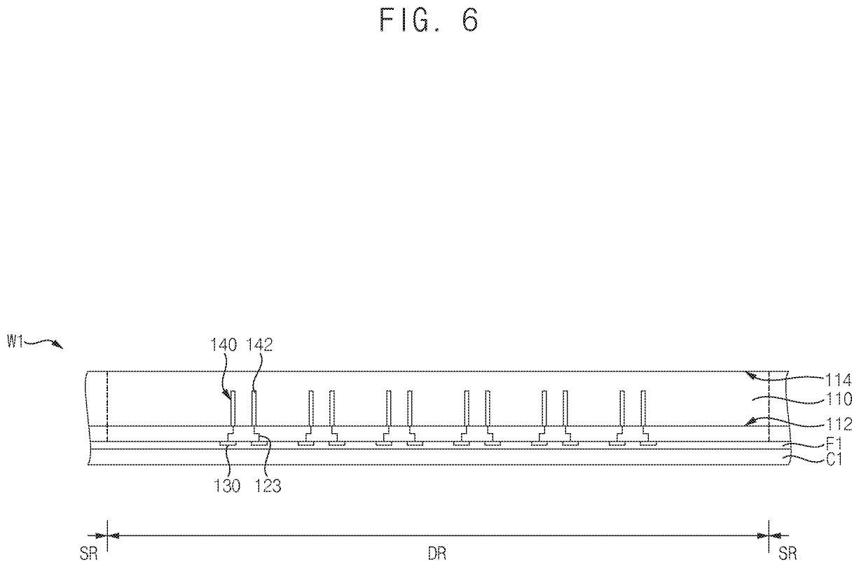

Referring to FIGS. 6 to 8, the backside surface of the first wafer W1, that is, the second surface 114 of the first substrate 110 may be grinded to expose second end portions of the through electrodes 142.

As illustrated in FIGS. 6 and 7, after the first wafer W1 is attached on a first substrate carrier C1 using a first adhesive film F1, the second surface 114 of the first substrate 110 may be partially removed until the end portions of the through electrodes 142 are exposed.

As illustrated in FIG. 8, the second surface 114 of the first substrate 110 may be partially removed by a grinding process, and the end portion of the through electrode 142 may be exposed by a plasma etching process (recess etching process). For example, a height H1 of the through electrode 142 protruding from the second surface 114 of the first substrate 110 after the plasma etching process may be within a range of 3 μm to 8 μm. The through electrode 142 may have a first diameter D1. The first diameter D1 may be within a range of 2 μm to 10 μm. A spacing distance between the through electrodes 142 of one electrode bundle 140 may be within a range of 1.5 μm to 5 μm.

Referring to FIG. 9, first, second and third passivation layers 152, 154 and 156 may be sequentially formed on the second surface 114 of the first substrate 110. The first, second and third passivation layers 152, 154 and 156 may be formed by a deposition process.

In particular, the first passivation layer 152 may cover the second end portions of the through electrodes 142 protruding from the second surface 114 of the first substrate 110. The first passivation layer 152 may be deposited on the second surface 114 of the first substrate 110 between the adjacent through electrodes 142.

The second passivation layer 154 may be formed on the first passivation layer 152. The second passivation layer 154 may be deposited relatively thicker on sidewalls of the through electrodes 142 facing each other due to the distance between the through electrodes 142 adjacent to each other, so that a space V between the through electrodes 142 may not be sufficiently filled. Accordingly, the second passivation layer 154 may not be deposited sufficiently on the second surface 114 of the first substrate 110 between the adjacent through electrodes 142.

The third passivation layer 156 may be formed on the second passivation layer 154. The third passivation layer 164 may be firstly deposited on the sidewalls of adjacent through electrodes 142 facing each other, so that the space V between the through electrodes 142 may not be sufficiently filled. Accordingly, the third passivation layer 156 may not be deposited on the second surface 114 of the first substrate 110 between the adjacent through electrodes 142.

For example, the first and third passivation layers 152 and 156 may include an oxide such as silicon oxide (SiO₂), and the second passivation layer 154 may include a nitride such as silicon nitride (SiN). Thicknesses of the first to third passivation layers 152, 154 and 156 may be within a range of 0.5 μm to 2.5 μm.

Referring to FIGS. 10 and 11, the third passivation layer 156 may be removed until a portion of the through electrode 142 is exposed, to form a backside insulating layer 150 having a trench 155.

For example, the third passivation layer 156 may be removed by a chemical mechanical polishing (CMP) process. The third passivation layer 156 may be removed until the second passivation layer 154 on the second surface 114 of the first substrate 110 is exposed. In this case, a portion of the second end portion of the through electrode 142 and a portion of the second passivation layer 154 may be removed together. As the third passivation layer 156 is removed, the trench 155 may be formed in the backside insulating layer 150 between the adjacent through electrodes 142.

The backside insulating layer 150 may be formed on the second surface 114 of the first substrate 110 and may expose end portions of the through electrodes 142. The backside insulating layer 150 may include the first passivation layer 152 on the second surface 114 of the first substrate 110 and covering the sidewall of the through electrode 142 protruding from the second surface 114 and the second passivation layer 154 formed on the first passivation layer 152. The trench 155 may be formed in the second passivation layer 154 between the adjacent through electrodes 142. The first passivation layer 152 may be exposed by the trench 155. An upper surface of the second passivation layer 154 and an exposed surface of the through electrode 142 may be positioned on the same plane.

For example, a depth T of the trench 155 may be within a range of 0.5 μm to 2.5 μm. A width W of the trench 155 may be within a range of 1 μm to 3 μm.

As illustrated in FIG. 11, four through electrodes 142 may be disposed in a pad region TR where one electrode pad is to be disposed. When viewed from a plan view, the trench 155 may have a diamond shape. The shape and width (W) of the trench 155 may be determined by the number of through electrodes 142 of one electrode bundle 140 and the spacing distance between the through electrodes. The depth T of the trench 155 may be determined by the thicknesses of the stacked first and second passivation layers 152 and 154.

Referring to FIGS. 12 to 15, electrode pads 162 as second bonding pads may be formed on the electrode bundles 140, respectively.

As illustrated in FIG. 12, a seed layer 160 may be formed on the backside insulating layer 150, and a photoresist pattern 20 having openings 21 that respectively expose the pad regions TR may be formed on the seed layer 160.

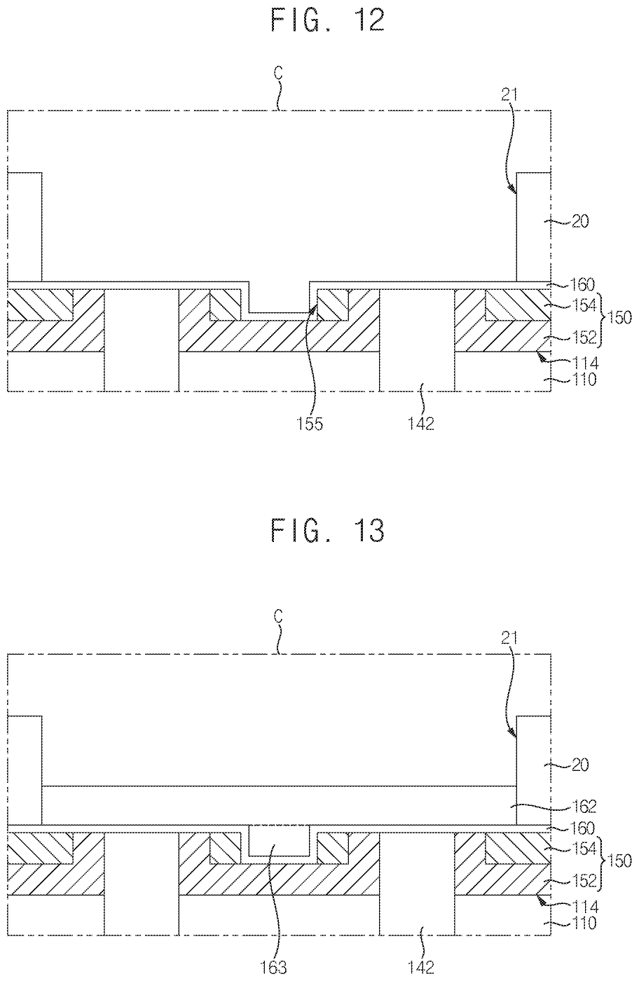

As illustrated in FIG. 13, the electrode pads 162 may be formed in the openings 21 of the photoresist pattern 20 by performing a plating process. In this case, the electrode pad 162 may include a protruding portion 163 filling the trench 155 formed in the upper surface of the backside insulating layer 150. The protruding portion 163 may serve as an anchor to increase adhesion between the electrode pad 162 and the backside insulating layer 150 and between the electrode pad 162 and the through electrodes 142. For example, the electrode pad 162 may include copper (Cu), aluminum (Al), tungsten, nickel (Ni), molybdenum (Mo), gold (Au), silver (Ag), chromium (Cr), Tin (Sn), titanium (Ti), and an alloy thereof.

As illustrated in FIGS. 14 and 15, the photoresist pattern 20 may be removed from the backside insulating layer 150, and portions of the seed layer exposed between the electrode pads 162 may be removed to form a seed layer pattern 161 under the electrode pad 162.

The electrode pads 162 may be respectively disposed in the pad regions TR. One electrode pad 162 may be disposed on four through electrodes 142 of one electrode bundle 140. That is, one electrode pad 162 may be electrically connected to four through electrodes 142 of one electrode bundle 140. When a power signal is transmitted through the electrode pad 162, the power signal may be transmitted through the four through electrodes 142 of the electrode bundle 140 connected in parallel to each other to the electrode pad 162, and the voltage drop (IR drop) effect can improve electrical transmission characteristics.

Referring to FIG. 16, first conductive bumps 180 as conductive connection members may be formed on the electrode pads 162, respectively.

In example embodiments, a protective layer pattern 164 (see FIG. 3) exposing at least a portion of the electrode pad 162 may be formed on the backside insulating layer 150, a seed layer may be formed on portions of the protective layer pattern 164 and the exposed electrode pads 162, and a photoresist pattern having openings that expose first conductive bump regions may be formed on the seed layer.

Then, the openings of the photoresist pattern may be filled up with a conductive material to form the first conductive bumps, the photoresist pattern may be removed from the first wafer W1, and portions of the seed layer exposed by the first conductive bumps may be removed to form a seed layer pattern 166 (see FIG. 3).

Each of the first conductive bumps 180 may include a first pillar bump 182 and a first solder bump 184 formed on the first pillar pump 182. For example, the first pillar bump 182 may have a single layer structure or a multilayer structure. The first pillar bump 182 may include a plating pattern layer containing copper. The first solder bump 184 may include solder. Alternatively, each of the first conductive bumps 180 may include only first pillar bump.

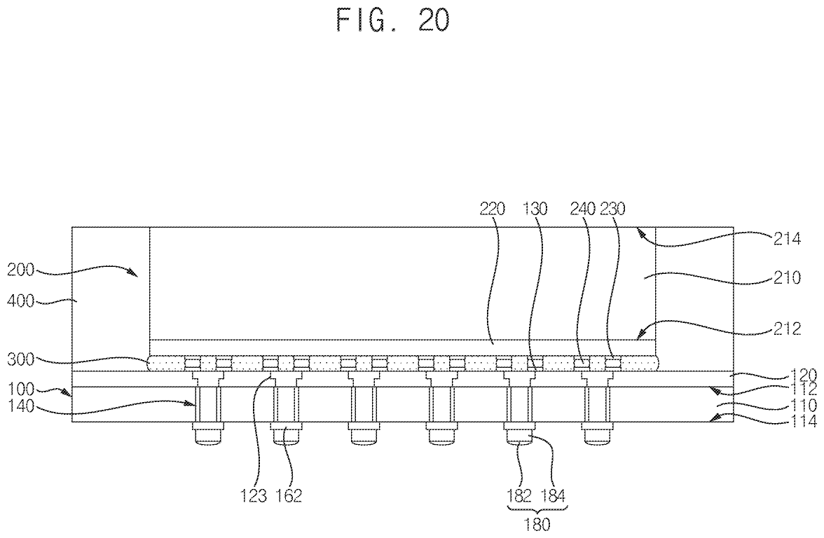

The step of forming the first conductive bumps 180 may be performed after stacking the second semiconductor chip 200 on the first wafer W1 and forming a sealing member 400 (see FIG. 19).

Referring to FIGS. 17 and 18, the second semiconductor chip 200 may be stacked on the first wafer W1. The second semiconductor chip 200 may be mounted on the first wafer W1 via second conductive bumps 240.

As illustrated in FIG. 17, after removing the first carrier substrate C1 from the first wafer W1, the structure of FIG. 16 may be turned over, and the first wafer W1 may be attached on a second carrier substrate C2 using a second adhesive film F2.

The second semiconductor chips 200 may be disposed on the first wafer W1 to correspond to die regions DR, respectively. The second semiconductor chip 200 may be attached on the first wafer W1 using an adhesive layer 300. The second semiconductor chip 200 may be disposed on the first wafer W1 such that a first surface 212 of a second substrate 210 of the second semiconductor chip 200 may face the first wafer W1. For example, the first surface 212 of the second substrate 210 may face the first surface 112 of the first substrate 110 of the first wafer W1.

The second semiconductor chip 200 may be attached on the first wafer W1 by a thermal compression process at a predetermined temperature (eg, about 400° C. or less). Through this thermal compression process, the second semiconductor chip 200 and the first wafer W1 may be bonded to each other.

In the thermal compression process, a non-conductive film as the adhesive layer may be liquefied and may have fluidity, and may flow between the second semiconductor chip 200 and the first wafer W1. The non-conductive film having fluidity may flow between the second conductive bumps 240 and then be cured to fill spaces between the second conductive bumps 240. A portion of the cured adhesive layer 300 may protrude from a side surface of the second semiconductor chip 200.

As illustrated in FIG. 18, the second conductive bump 240 of the second semiconductor chip 200 may be bonded to the first bonding pad 130 of the first semiconductor chip through the thermal compression process. The first bonding pad 130 may be electrically connected to the electrode pad 162 by the metal wirings 123 of the first front wiring layer 120 and by the through electrode 142.

In particular, the second semiconductor chip 200 may include a second substrate 210, a second front wiring layer 220 and a plurality of third bonding pads 230. In addition, the second semiconductor chip 200 may include the second conductive bumps 240 as second conductive connection members respectively provided on the third bonding pads 230. The second semiconductor chip 200 may be mounted on the first semiconductor chip via the second conductive bumps 240. For example, the second conductive bumps 240 may include solder bumps.

The second substrate 210 may have a first surface 212 and a second surface 214 opposite to the first surface 212. The first surface may be an active surface, and the second surface may be an inactive surface. Circuit elements may be formed on the first surface 212 of the second substrate 210. The circuit element may include a plurality of memory devices. Examples of the memory device include a volatile semiconductor memory device and a non-volatile semiconductor memory device. An insulation interlayer covering the circuit elements may be formed on the first surface 212 of the second substrate 210.

The second front wiring layer 220 may include a plurality of insulating layers and metal wirings 223 in the insulating layers. For example, the insulating layers may be formed to include an oxide such as silicon oxide, carbon-doped oxide, or fluorine-doped oxide. The metal wirings may include a metal material such as aluminum (Al) or copper (Cu).

A plurality of third bonding pads 230 may be provided on the second front wiring layer 220. The third bonding pad 230 may be provided on an uppermost wiring among the metal wirings 223. For example, the third bonding pads 230 may include copper (Cu), aluminum (Al), tungsten, nickel (Ni), molybdenum (Mo), gold (Au), silver (Ag), chromium (Cr), tin (Sn), titanium (Ti), or an alloy thereof.

The numbers, sizes, arrangements, etc. of the metal wirings and the third bonding pads of the second front wiring layer are provided as examples, and it will be appreciated that the present inventive concept is not limited thereto.

The second conductive bumps 240 may be respectively provided on the third bonding pads 230. A pitch between the second conductive bumps 240 may be within a range of 15 μm to 35 μm. For example, the second conductive bump 240 of the second semiconductor chip 200 may be bonded to the first bonding pad 130 of the first semiconductor chip through a flip chip bonding process. Accordingly, the third bonding pad 230 of the second semiconductor chip 200 may be electrically connected to the first bonding pad 130 of the first semiconductor chip by the second conductive bump 240.

The adhesive layer 300 may be provided to fill a space between the second conductive bumps 240 between the first semiconductor chip and the second semiconductor chip 200. For example, the adhesive layer may include a non-conductive film (NCF).

Referring to FIG. 19, a sealing member 400 may be formed on the first wafer W1 to cover the second semiconductor chip 200.

In example embodiments, the sealing member 400 may be formed to fill gaps between the second semiconductor chips 200 on the first wafer W1. The sealing member 400 may be formed to surround the second semiconductor chips 200. An upper surface, that is, a backside surface of the second semiconductor chip 200 may be exposed by the sealing member 400. The sealing member 400 may be formed by a dispensing process or a spin coating process. For example, the sealing member 400 may include a thermosetting resin or the like.

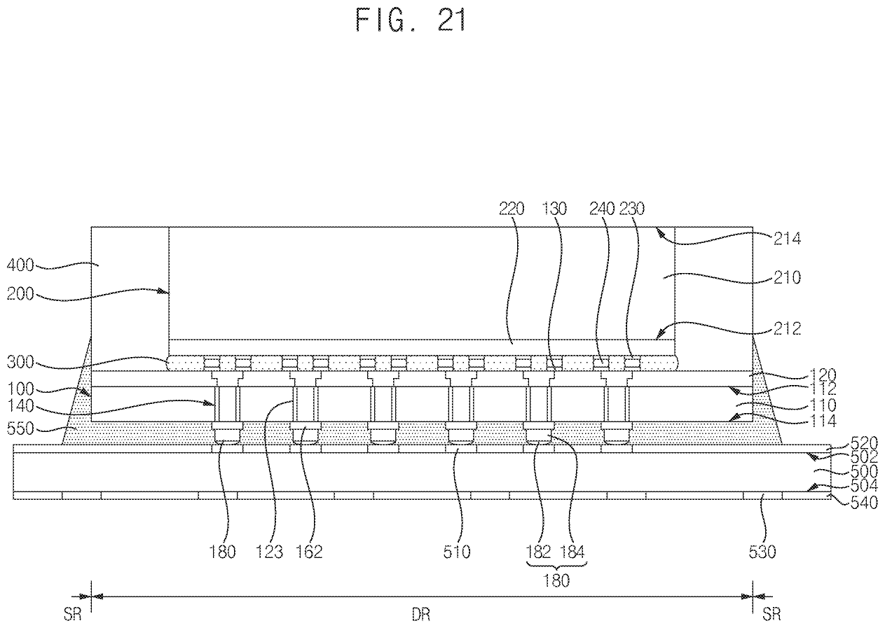

Referring to FIG. 20, the first wafer W1 and the sealing member 400 may be cut along the scribe lane region SR to form an individualized first semiconductor chip 100. The first wafer W1 may be cut by a sawing process. Thus, a stack package in which the second semiconductor chip 200 is stacked on the first semiconductor chip 100 may be formed.

Referring to FIG. 21, the stack package may be mounted on a package substrate 500.

In example embodiments, the first semiconductor chip 100 may be mounted on the package substrate 500 via the first conductive bumps 280. The first semiconductor chip 100 may be disposed such that the second surface 114 of the first substrate 110 of the first semiconductor chip 100 faces the package substrate 500. The first conductive bump 180 of the first semiconductor chip 100 may be bonded to a substrate pad 510 on an upper surface 502 of the package substrate 500.

Then, an underfill member 550 may be underfilled between the first semiconductor chip 100 and the package substrate 500. While moving a dispenser nozzle along an edge of the first semiconductor chip 100, an underfill solution may be dispensed between the first semiconductor chip 100 and the package substrate 500, and the underfill solution may be cured to form the underfill member 550.

For example, the underfill member may include an epoxy material to reinforce a gap between the first semiconductor chip 100 and the package substrate 500.

Then, external connection members 600 (see FIG. 1) may be formed on external connection pads 530 on a lower surface 504 of the package substrate 500 to complete the semiconductor package 10 (see FIG. 1).

FIG. 22 is a plan view illustrating an electrode bundle having through electrodes exposed by a backside insulating layer of a lower semiconductor chip in accordance with example embodiments.

Referring to FIG. 22, one electrode bundle 140 may have three through electrodes 142 disposed adjacent to each other in a pad region TR. A backside insulating layer 150 may have one trench 155 formed between the three through electrodes 142. When viewed from a plan view, the trench 155 may have a triangular shape.

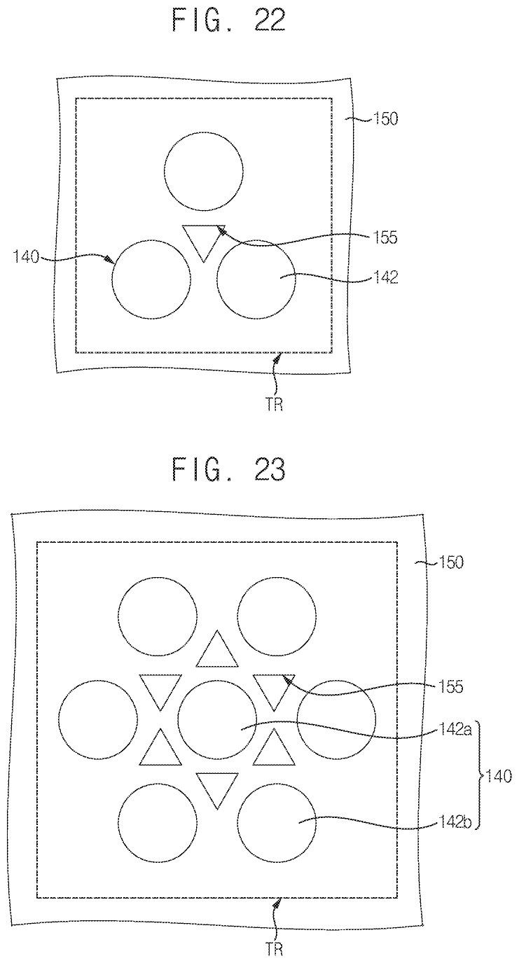

FIG. 23 is a plan view illustrating an electrode bundle having through electrodes exposed by a backside insulating layer of a lower semiconductor chip in accordance with example embodiments.

Referring to FIG. 23, one electrode bundle 140 may have seven through electrodes 142 disposed adjacent to each other in a pad region TR. One first through electrode 142a may be disposed in the center of the pad region TR, and six second through electrodes 142b may be spaced apart from each other along a circumferential direction around the first through electrode 142b. A backside insulating layer 150 may include six trenches 155. The six trenches 155 may be spaced apart from each other along the circumferential direction around the first through electrode 142b. One trench 155 may be formed between the first through electrode 142a and two adjacent second through electrodes 142b. When viewed from a plan view, the trench 155 may have a triangular shape.

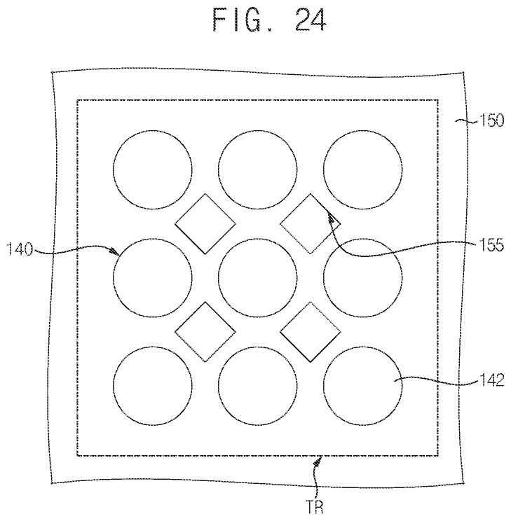

FIG. 24 is a plan view illustrating an electrode bundle having through electrodes exposed by a backside insulating layer of a lower semiconductor chip in accordance with example embodiments.

Referring to FIG. 24, one electrode bundle 140 may have nine through electrodes 142 disposed adjacent to each other in a pad region TR. Nine through electrodes 142 may be arranged in a 3×3 matrix form. A backside insulating layer 150 may include four trenches 155. The four trenches 155 may be arranged in a 2×2 matrix form. One trench 155 may be formed between the four through electrodes 142 (e.g., in a middle region among four through electrodes 142 that form a 2×2 matrix). When viewed from a plan view, the trench 155 may have a diamond shape.

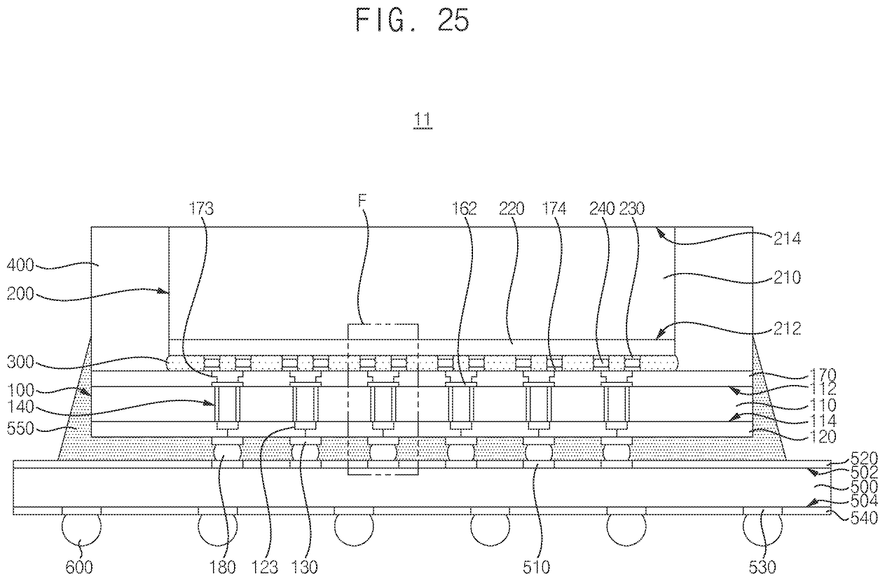

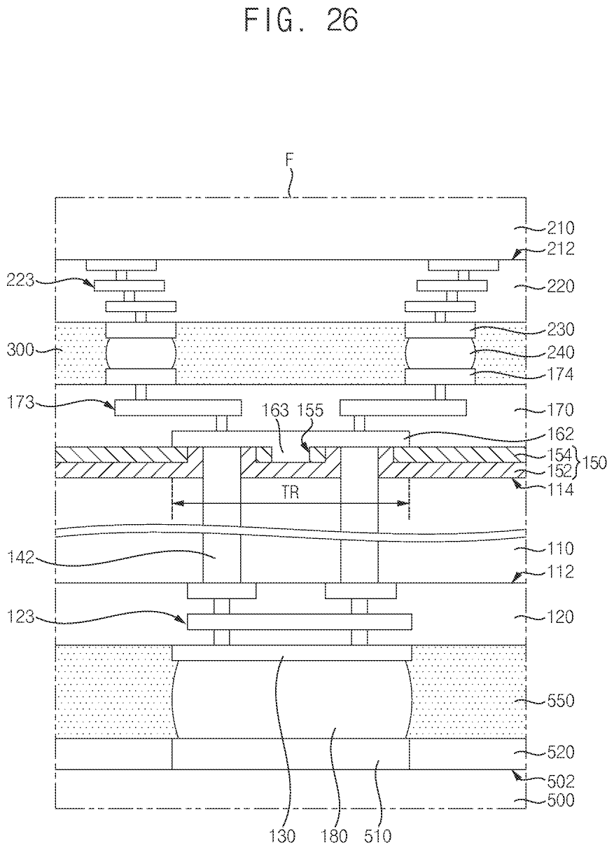

FIG. 25 is a cross-sectional view illustrating a semiconductor package in accordance with example embodiments. FIG. 26 is an enlarged cross-sectional view illustrating portion ‘F’ in FIG. 25. The semiconductor package may be substantially the same as the semiconductor package described with reference to FIGS. 1 to 4 except for arrangements of first and second test pads. Thus, same reference numerals will be used to refer to the same or like elements and any further repetitive explanation concerning the above elements will be omitted.

Referring to FIGS. 25 and 26, a semiconductor package 11 may include a first semiconductor chip 100 and a second semiconductor chip 200 stacked on the first semiconductor chip 100.

In example embodiments, the first semiconductor chip 100 may include a first substrate 110, a first front wiring layer 120, a plurality of first bonding pads 130, a plurality of electrode bundles 140, a backside insulating layer 150, a plurality of electrode pads 162 as redistribution pads, a first backside wiring layer 170, and a plurality of second bonding pads 174.

The first front wiring layer 120 may be provided on a first surface 112 of the first substrate 110, that is, an active surface. The first front wiring layer 120 may include a plurality of insulating layers and metal wirings 123 in the insulating layers. The first bonding pad 130 may be provided on an uppermost wiring among the metal wirings 123. The plurality of electrode bundles 140 may be arranged in an array form. Each of the electrode bundles 140 may include at least three through electrodes (through silicon vias, TSVs) 142 adjacent to each other.

For example, one electrode bundle 140 may include four through electrodes 142 adjacent to each other. First end portions of the four through electrodes 142 may be electrically connected to one first bonding pad 130 through the metal wirings 123 of the first front wiring layer 120. However, it may not be limited thereto, and for example, four through electrodes 142 may penetrate through the first front wiring layer and directly contact one first bonding pad 130.

The backside insulating layer 150 may be provided on a second surface 114 of the first substrate 110, that is, a backside surface. The backside insulating layer 150 may be provided on the second surface 114 of the first substrate 110 to expose end portions, e.g., second end portions of the through electrodes 142. The backside insulating layer 150 may have at least one trench 155 formed between the end portions of the through electrodes 142 of one electrode bundle 140.

The electrode pads 162 as the redistribution pads may be provided on the backside insulating layer 150. The electrode pads 162 may be respectively disposed on the electrode bundles 140. One electrode pad 162 may be disposed on exposed surfaces of the through electrodes 142 of one electrode bundle 140. One electrode pad 162 may be electrically connected to the through electrodes 142 of one electrode bundle 140.

The electrode pad 162 may include a protruding porting 163 filling the trench 155 formed in an upper surface of the backside insulating layer 150. The protruding portion 163 may serve as an anchor to increase adhesion between the electrode pad 162 and the backside insulating layer 150 and between the electrode pad 162 and the through electrodes 142.

In example embodiments, the first backside wiring layer 170 may be provided on the backside insulating layer 150 and have metal wirings 173 electrically connected to the plurality of electrode pads 162. The plurality of second bonding pads 174 may be provided on the first backside wiring layer 170 and may be electrically connected to the metal wirings 173.

The second bonding pad 174 may be provided on an uppermost wiring among the metal wirings 173. For example, one redistribution pad 162 may be electrically connected to the four second bonding pads 174 through the metal wirings of the first backside wiring layer. However, the invention is not limited thereto, and for example, one redistribution pad 162 may be electrically connected to two, three, five or more second bonding pads 174.

Alternatively, the second bonding pad 174 may be directly formed on a portion of the redistribution pad 162. In this case, the redistribution pad 162 serves as the metal wirings, and the metal wirings may be omitted.

The numbers, sizes, arrangements, etc. of the metal wirings of the first backside wiring layer and the second bonding pads are provided as examples, and it will be understood that the present inventive concept is not limited thereto.

Thus, the second bonding pad 174 may be electrically connected to the first bonding pad 130 by the metal wirings 173 of the first backside wiring layer 170, the redistribution pad 162, the through electrode 142 and the metal wirings 123 of the first front wiring layer 120.

In example embodiments, the first semiconductor chip 100 may further include first conductive bumps 180 as first conductive connection members respectively provided on the first bonding pads 130. The first semiconductor chip 100 may be mounted on a package substrate 500 via the first conductive bumps 180. The first semiconductor chip 100 may be disposed such that the first surface 112 of the first substrate 110 of the first semiconductor chip 100 faces the package substrate 500. The first conductive bump 180 of the first semiconductor chip 100 may be bonded to a substrate pad 510 on an upper surface 502 of the package substrate 500.

In example embodiments, the second semiconductor chip 200 may include a second substrate 210, a second front wiring layer 220 and a plurality of third bonding pads 230. In addition, the second semiconductor chip 200 may further include second conductive bumps 240 as second conductive connection members respectively provided on the third bonding pads 230. The second semiconductor chip 200 may be mounted on the first semiconductor chip 100 via the second conductive bumps 240.

The second conductive bumps 240 may be respectively provided on the third bonding pads 230. A pitch between adjacent ones of the second conductive bumps 240 may be within a range of 15 μm to 35 μm. For example, the second conductive bumps 240 of the second semiconductor chip 200 may be bonded to the second bonding pads 174 of the first semiconductor chip 100 by a flip chip bonding process. Accordingly, the third bonding pad 230 of the second semiconductor chip 200 may be electrically connected to the second bonding pad 174 of the first semiconductor chip 100 through the second conductive bump 240.

Hereinafter, a method of manufacturing the semiconductor package of FIG. 25 will be described.

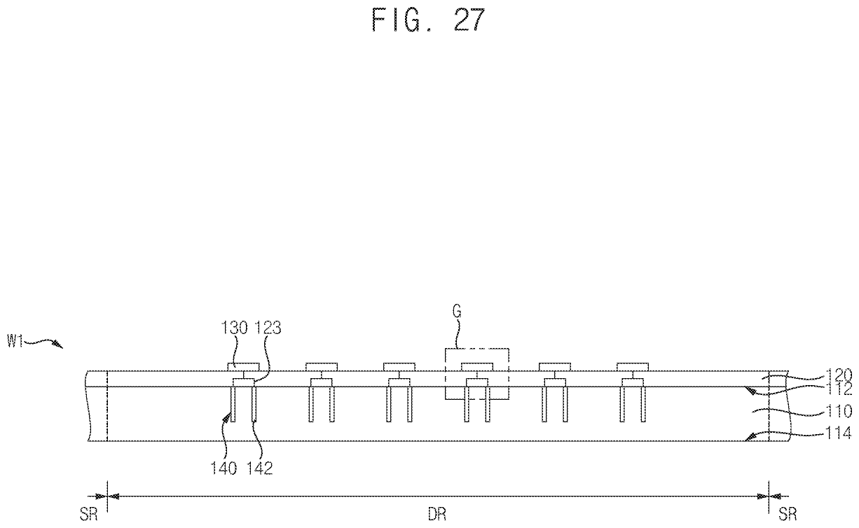

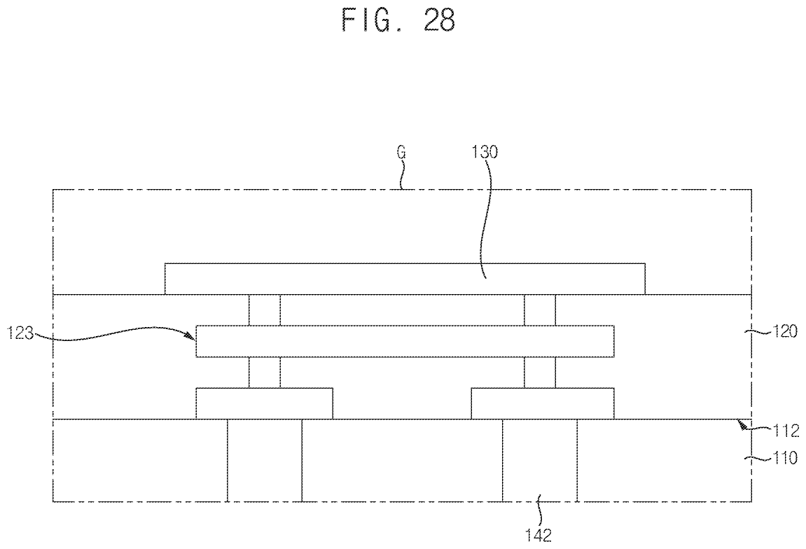

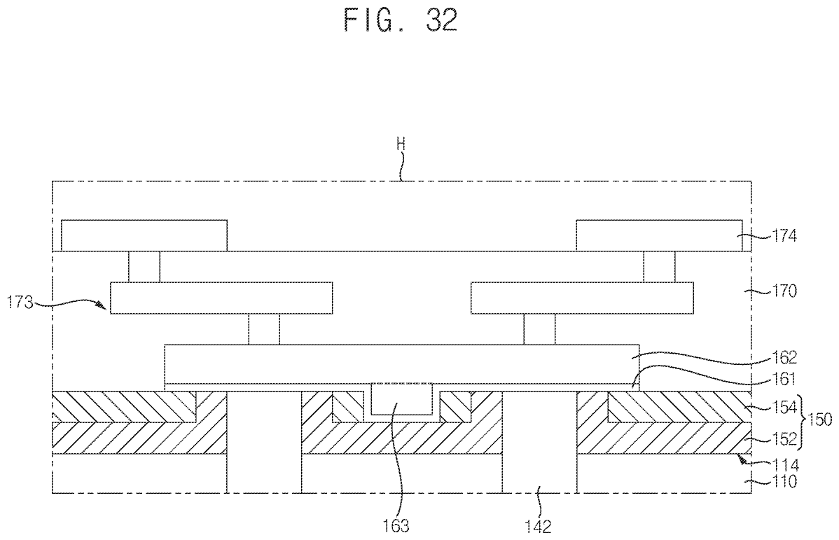

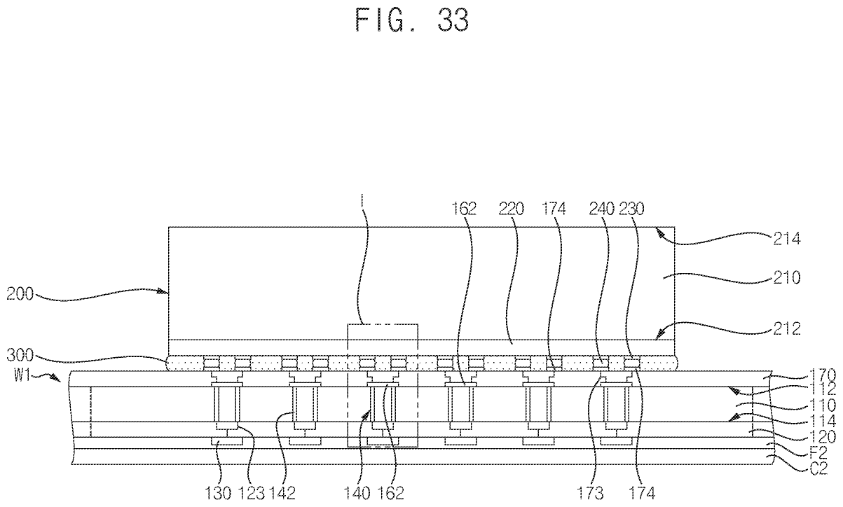

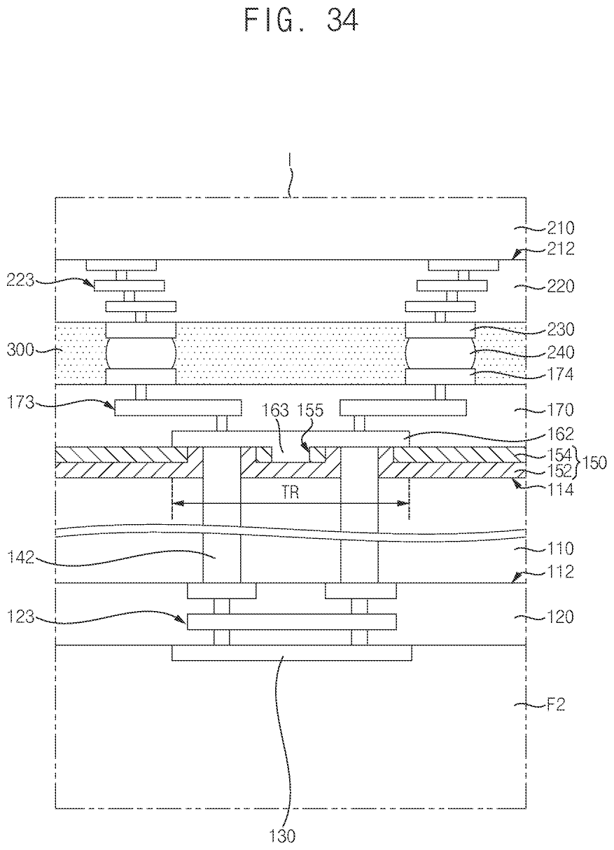

FIGS. 27 to 36 are views illustrating a method of manufacturing a semiconductor package in accordance with example embodiments. FIGS. 27, 29 to 31, 33, 35 and 36 are cross-sectional views illustrating a method of manufacturing a semiconductor package in accordance with example embodiments. FIG. 28 is an enlarged cross-sectional view illustrating portion ‘G’ in FIG. 27. FIG. 32 is an enlarged cross-sectional view illustrating portion ‘H’ in FIG. 31. FIG. 34 is an enlarged cross-sectional view illustrating portion ‘I’ in FIG. 33.

Referring to FIGS. 27 and 28, processes the same as or similar to the processes described with reference to FIG. 5 may be performed to provide a first wafer W1 including a plurality of first semiconductor chips formed therein.

In example embodiments, the first wafer W1 may include a first front wiring layer 120 provided on a first surface 112 of a first substrate 110, a plurality of first bonding pads 130 on the first front wiring layer 120, and a plurality of electrode bundles 140 in the first substrate 110.

The first front wiring layer 120 may include a plurality of insulating layers and metal wirings 123 in the insulating layers. The first bonding pad 130 may be provided on an uppermost wiring among the metal wirings 123. The plurality of electrode bundles 140 may be arranged in an array form. Each of the electrode bundles 140 may include at least three through electrodes (through silicon vias, TSVs) 142 adjacent to each other. The through electrode 142 may extend by a predetermined depth from the first surface 112 of the first substrate 110.

For example, one electrode bundle 140 may include four through electrodes 142 adjacent to each other. First end portions of the four through electrodes 142 may be electrically connected to one first bonding pad 130 by the metal wirings of the first front wiring layer. However, the invention is not limited thereto, and for example, four through electrodes 142 may penetrate the first front wiring layer and directly contact one first bonding pad 130.

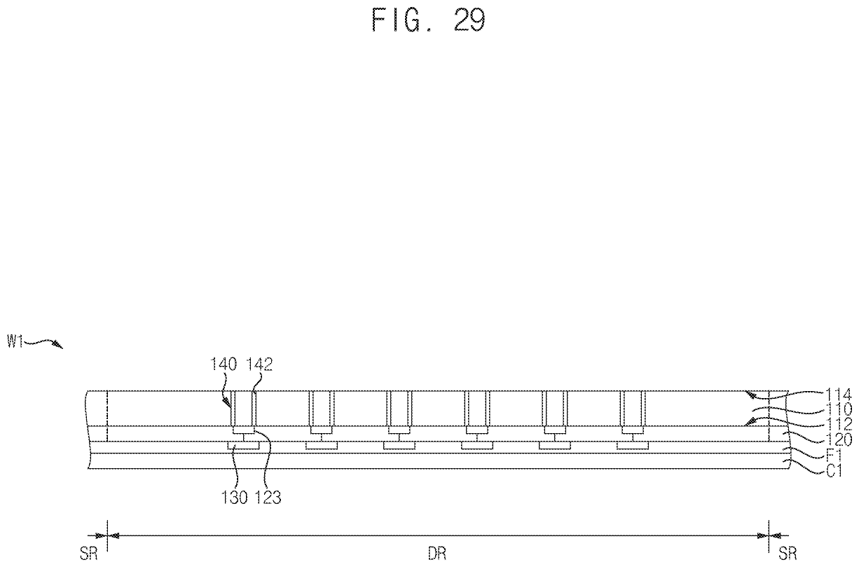

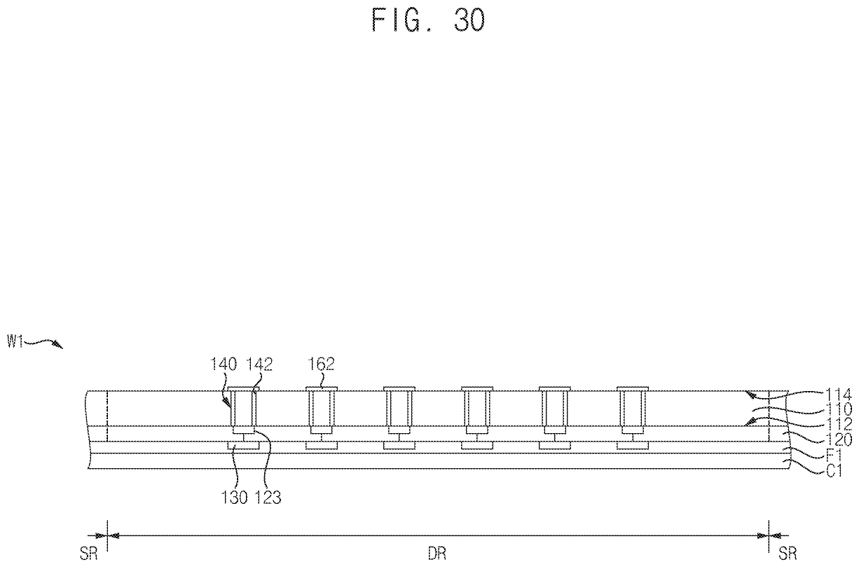

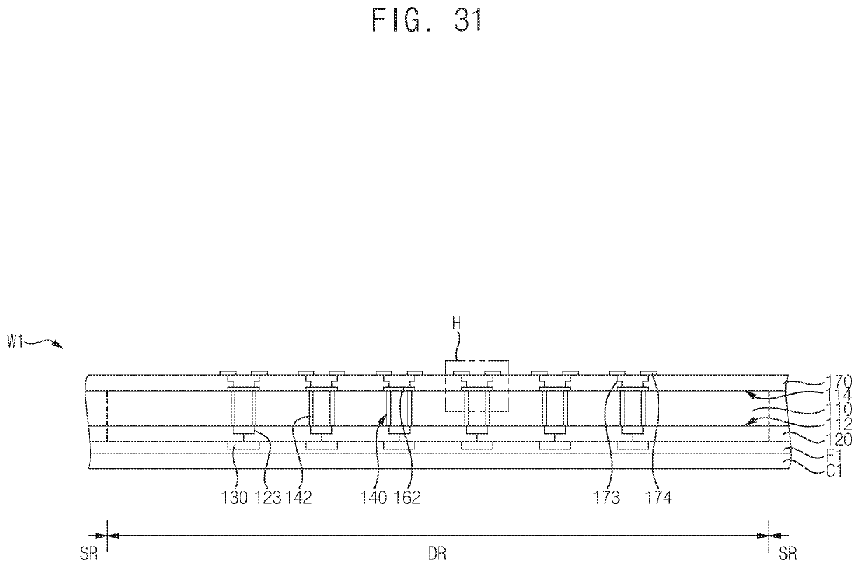

Referring to FIGS. 29 and 30, processes the same as or similar to the processes described with reference to FIGS. 6 to 15 may be performed to form a backside insulating layer 150 (see FIG. 15) that exposes end portions of the through electrodes 142 on a second surface 112 of the first substrate 122 and to form electrode pads 162 as redistribution pads on the backside insulating layer 150.

In example embodiments, as illustrated in FIG. 15, the backside insulating layer 150 may include a first passivation layer 152 covering the second surface 114 of the first substrate and sidewalls of end portions of the through electrodes 142 protruding from the second surface 114 and a second passivation layer 154 stacked on the first passivation layer 152. A trench 155 may be provided in the second passivation layer 154 between adjacent through electrodes 142. The first passivation layer 152 may be exposed by the trench 155. An upper surface of the second passivation layer 154 may be positioned on the same plane as an exposed surface of the one end portion of the through electrode 142.

The electrode pads 162 may be respectively formed on the electrode bundles 140. For example, one electrode pad 162 may be disposed on four through electrodes 142 of one electrode bundle 140. That is, one electrode pad 162 may be electrically connected to four through electrodes 142 of one electrode bundle 140. Referring to FIG. 32, in this case, the electrode pad 162 may include a protruding portion 163 filling the trench 155 formed in the upper surface of the backside insulating layer 150. The protruding portion 163 may serve as an anchor to increase adhesion between the electrode pad 162 and the backside insulating layer 150 and between the electrode pad 162 and the through electrodes 142.

Referring to FIGS. 31 and 32, a first backside wiring layer 170 and a plurality of second bonding pads 274 may be formed on the backside insulating layer 150.

In example embodiments, the first backside wiring layer 170 may be formed by performing a wiring process called a BEOL process. The first backside wiring layer 170 may include a plurality of insulating layers and metal wirings 173 in the insulating layers. For example, the insulating layers may be formed to include an oxide such as silicon oxide, carbon-doped oxide, or fluorine-doped oxide. The metal wirings may include a metal material such as aluminum (Al) or copper (Cu).

The second bonding pad 174 may be provided on an uppermost wire among the metal wirings 173. For example, one electrode pad 162 may be electrically connected to the four second bonding pads 174 through the metal wirings of the first backside wiring layer. However, it may not be limited thereto, and for example, one electrode pad 162 may be electrically connected to two, three, five or more second bonding pads 174.

The numbers, sizes, arrangements, etc. of the metal wirings of the first backside wiring layer and the second bonding pads are provided as examples, and it will be understood that the present inventive concept is not limited thereto.

Thus, the second bonding pad 174 may be electrically connected to the first bonding pad 130 by the metal wirings 173 of the first backside wiring layer 170, the electrode pad 162, the through electrode 142 and the metal wirings 123 of the first front wiring layer 120.

Referring to FIGS. 33 and 34, processes the same as or similar to the processes described with reference to FIGS. 17 and 18 may be performed to stack a second semiconductor chip 200 on the first wafer W1. The semiconductor chip 200 may be mounted on the first wafer W1 via second conductive bumps 240.

The second semiconductor chips 200 may be disposed on the first wafer W1 to correspond to die regions DR, respectively. The second semiconductor chip 200 may be attached on the first wafer W1 using an adhesive layer 300. The second semiconductor chip 200 may be disposed such that a first surface 212 of a second substrate 210 of the second semiconductor chip 200 faces the first wafer W1. For example, the first surface 212 of the second substrate 210 may face the first surface 112 of the first substrate 110 of the first wafer W1.

The second conductive bump 240 of the second semiconductor chip 200 may be bonded to the second bonding pad 174 of the first semiconductor chip by a thermal compression process. Accordingly, a third bonding pad 230 of the second semiconductor chip 200 may be electrically connected to the second bonding pad 174 of the first semiconductor chip through the second conductive bump 240.

The adhesive layer 300 may be provided to fill a space between the second conductive bumps 240 between the first semiconductor chip and the second semiconductor chip 200. For example, the adhesive layer may include a non-conductive film (NCF).

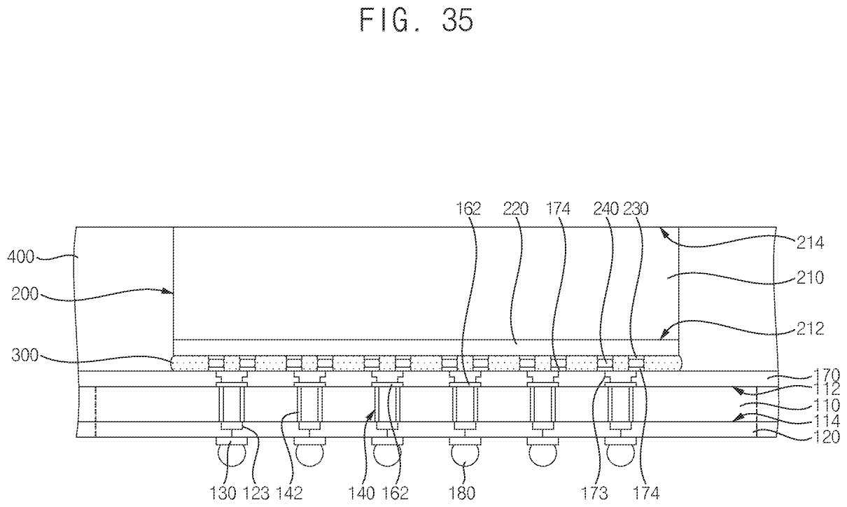

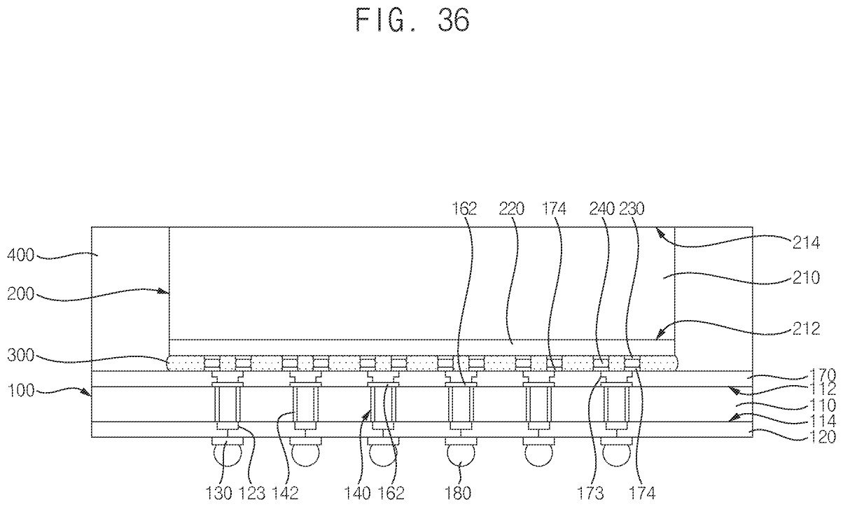

Referring to FIG. 35, processes the same as or similar to the processes described with reference to FIG. 19 may be performed to form a sealing member 400 that covers the second semiconductor chip 200 on the first wafer W1.

In example embodiments, the sealing member 400 may be formed to fill gaps between the second semiconductor chips 200 on the first wafer W1. The sealing member 400 may be formed to surround the second semiconductor chips 200. An upper surface, that is, a backside surface of the second semiconductor chip 200 may be exposed by the sealing member 400. The sealing member 400 may be formed by a dispensing process or a spin coating process. For example, the sealing member 400 may include a thermosetting resin or the like.

Referring to FIG. 36, processes the same as or similar to the processes described with reference to FIG. 20 may be performed to cut the first wafer W1 and the sealing member 400 along a scribe lane region SR, to form an individual first semiconductor chip 100. The first wafer W1 may be cut by a sawing process. Thus, a stack package in which the second semiconductor chip 200 is stacked on the first semiconductor chip 100 may be formed.

Then, processes the same as or similar to the processes described with reference to FIG. 21 may be performed to mount the stacked package on a package substrate 500 (see FIG. 25) to complete the semiconductor package 11 (see FIG. 25).

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the invention.

What is claimed is:

1. A semiconductor package, comprising:
a package substrate;
a first semiconductor chip stacked on the package substrate, the first semiconductor chip comprising:
a first substrate having first and second surfaces opposite to each other,
a plurality of electrode bundles each comprising a plurality of through electrodes that are adjacent to each other, the plurality of through electrodes penetrating the first substrate,
a backside insulating layer on the second surface of the first substrate through which end portions of the plurality of through electrodes are exposed, and
a plurality of electrode pads respectively provided on the plurality of electrode bundles;
a second semiconductor chip stacked on the first semiconductor chip by way of conductive bumps; and
an adhesive layer filling a space between the conductive bumps between the first semiconductor chip and the second semiconductor chip, the adhesive layer attaching the first semiconductor chip to the second semiconductor chip,
wherein the backside insulating layer has a first trench formed between the end portions of the plurality of through electrodes of a first electrode bundle of the plurality of electrode bundles,
wherein a first electrode pad of the plurality of electrode pads is electrically connected to the plurality of through electrodes of the first electrode bundle of the plurality of electrode bundles, and
wherein the first electrode pad has a protruding portion that fills the first trench of the backside insulating layer.

2. The semiconductor package of claim 1, wherein the backside insulating layer comprises:
a first passivation layer covering the second surface of the first substrate and sidewalls of the end portions of the plurality of through electrodes protruding from the second surface; and
a second passivation layer formed on the first passivation layer.

3. The semiconductor package of claim 2, wherein the first trench is provided in the second passivation layer between adjacent through electrodes of the plurality of through electrodes in the first electrode bundle.

4. The semiconductor package of claim 3, wherein the first passivation layer is exposed through a bottom face of the trench.

5. The semiconductor package of claim 3, wherein an upper surface of the second passivation layer is positioned on the same plane as an exposed surface of the end portion of the plurality of through electrodes.

6. The semiconductor package of claim 1, wherein a depth of the trench is within a range of 0.5 μm to 2.5 μm.

7. The semiconductor package of claim 1, wherein a width of the trench is within a range of 1 μm to 3 μm.

8. The semiconductor package of claim 1, wherein the second semiconductor chip is disposed such that the second semiconductor chip faces the first surface of the first substrate.

9. The semiconductor package of claim 1, wherein the first semiconductor chip further comprises:
a backside wiring layer on the backside insulating layer, the backside wiring layer comprising metal wirings electrically connected to the plurality of electrode pads; and
a plurality of second bonding pads on the backside wiring layer and electrically connected to the metal wirings.

10. The semiconductor package of claim 9, wherein the conductive bumps are bonded to the plurality of second bonding pads respectively.

11. A semiconductor package, comprising:
a first semiconductor chip comprising:
a first substrate having first and second surfaces opposite to each other,
a plurality of electrode bundles arranged in an array in the first substrate, each of the plurality of electrode bundles comprising a plurality of through electrodes penetrating the first substrate,
a plurality of first bonding pads on the first surface of the first substrate and electrically connected to the plurality of through electrodes,
a backside insulating layer on the second surface of the first substrate through which end portions of the plurality of through electrodes are exposed, and
a plurality of electrode pads respectively provided on the plurality of electrode bundles; and
a second semiconductor chip comprising a second substrate having first and second surfaces opposite to each other and a plurality of third bonding pads provided on the first surface of the second substrate, the second semiconductor chip being stacked on the first semiconductor chip by way of conductive bumps formed on the third bonding pads respectively,
wherein the backside insulating layer has a first trench formed between the plurality of through electrodes of a first electrode bundle of the plurality of electrode bundles, and
wherein a first electrode pad is disposed on the plurality of through electrodes of the first electrode bundle and comprises a protruding portion that fills the first trench of the backside insulating layer.

12. The semiconductor package of claim 11, wherein the backside insulating layer comprises:
a first passivation layer covering the second surface of the first substrate and sidewalls of the end portions of the plurality of through electrodes protruding from the second surface; and
a second passivation layer formed on the first passivation layer.

13. The semiconductor package of claim 12, wherein the first trench is provided in the second passivation layer between adjacent through electrodes of the plurality of through electrodes in the first electrode bundle.

14. The semiconductor package of claim 13, wherein the first passivation layer is exposed through a bottom face of the trench.

15. The semiconductor package of claim 13, wherein an upper surface of the second passivation layer is positioned on the same plane as an exposed surface of the end portion of the plurality of through electrodes.

16. The semiconductor package of claim 11, wherein a depth of the trench is within a range of 0.5 μm to 2.5 μm.

17. The semiconductor package of claim 11, wherein the first surface of the second substrate faces the second surface of the first substrate.

18. The semiconductor package of claim 11, wherein the first semiconductor chip further comprises:
a backside wiring layer on the backside insulating layer, the backside wiring layer comprising metal wirings electrically connected to the plurality of electrode pads; and
a plurality of second bonding pads on the backside wiring layer and electrically connected to the metal wirings.

19. The semiconductor package of claim 18, wherein the conductive bumps are bonded to the plurality of second bonding pads respectively.

20. A semiconductor package, comprising:
a first semiconductor chip comprising:
a first substrate having first and second surfaces opposite to each other,
a plurality of electrode bundles arranged in an array in the first substrate, each of the plurality of electrode bundles comprising a plurality of through electrodes penetrating the first substrate,
a plurality of first bonding pads on the first surface of the first substrate and electrically connected to the plurality of through electrodes,
a backside insulating layer on the second surface of the first substrate through which end portions of the plurality of through electrodes are exposed, and
a plurality of electrode pads respectively provided on the plurality of electrode bundles;
a second semiconductor chip stacked on the first semiconductor chip by way of conductive bumps;
an adhesive layer filling a space between the conductive bumps between the first semiconductor chip and the second semiconductor chip, the adhesive layer attaching the first semiconductor chip to the second semiconductor chip; and
a sealing member on the first semiconductor chip covering a side surface of the second semiconductor chip,
wherein the backside insulating layer comprises:
a first passivation layer covering the second surface of the first substrate and sidewalls of the end portions of the plurality of through electrodes protruding from the second surface; and
a second passivation layer formed on the first passivation layer and having a first trench formed between the plurality of through electrodes of a first electrode bundle, and
wherein a first electrode pad is disposed on the plurality of through electrodes of the first electrode bundle and comprises a protruding portion that fills the first trench of the second passivation layer.
